(19) United States
(12) Patent Application Publication
(10) Pub. No.: US 2017/0236841 A1
(43) Pub. Date: Aug. 17, 2017

(54) FIN WITH AN EPITAXIAL CLADDING LAYER

(71) Applicant: QUALCOMM Incorporated, San Diego, CA (US)

(72) Inventors: Stanley Seungchul Song, San Diego, CA (US); Choh Fei Yeap, Hsinchu City (TW); Jeffrey Junhao Xu, San Diego, CA (US); Kern Rim, San Diego, CA (US); Vladimir Machkaoutsan, Wezemaal (BE)

(21) Appl. No.: 15/160,192

(22) Filed: May 20, 2016

Related U.S. Application Data
(60) Provisional application No. 62/293,920, filed on Feb. 11, 2016.

(51) Int. Cl. H01L 27/12; H01L 21/84; H01L 29/267; H01L 29/165; H01L 29/06; H01L 29/04

(52) U.S. Cl. CPC H01L 27/1211; H01L 29/0649; H01L 29/045; H01L 29/267; H01L 29/165; H01L 21/845

(57) ABSTRACT

A device includes a substrate, a fin, and an isolation layer. The device also includes an epitaxial cladding layer on a sidewall of the fin. The epitaxial cladding layer has a substantially uniform thickness and has a continuous lattice structure at an interface with the sidewall. The epitaxial cladding layer is positioned above the isolation layer.

### I. CROSS-REFERENCE TO RELATED APPLICATIONS

The present application claims benefit of U.S. Provisional Patent Application No. 62/293,920, filed Feb. 11, 2016, entitled “FIN WITH AN EPITAXIAL CLADDING LAYER,” which is incorporated by reference in its entirety.

### II. FIELD

The present disclosure is generally related to a fin with an epitaxial cladding layer.

### III. DESCRIPTION OF RELATED ART

Advances in technology have resulted in smaller and more powerful computing devices. For example, a variety of portable personal computing devices, including wireless telephones such as mobile and smart phones, tablets and laptop computers, are small, lightweight, and easily carried by users. These devices can communicate voice and data packets over wireless networks. Further, many such devices incorporate additional functionality such as a digital still camera, a digital video camera, a digital recorder, and an audio file player. Also, such devices can process executable instructions, including software applications, such as a web browser application, that can be used to access the Internet. As such, these devices can include significant computing capabilities.

A non-planar field effect transistor (e.g., a finFET) may include one or more fins formed on a substrate. An epitaxial cladding layer on a fin may be used to form a channel providing carrier mobility. Epitaxial deposition of a cladding material on the fin may result in formation of a faceted cladding layer with non-uniform thickness, e.g., as described in U.S. Patent Application Publication No. 2015/0228761. For example, the cladding layer may be diamond-shaped. Non-uniformity in the thickness of the cladding layer has a detrimental impact on device performance. An attempt to grow an epitaxial cladding layer having a uniform thickness is described in U.S. Pat. No. 8,809,947 (Akarvardar). Akarvardar describes timed epitaxial deposition to align a side epitaxial layer on a sidewall of a fin with an upper epitaxial layer on top of the fin. See Akarvardar, col. 5, ln. 65—col. 6, ln. 2. The side epitaxial layer may not have a continuous lattice structure with the upper epitaxial layer. In addition, timing of the epitaxial deposition to align the side epitaxial layer with the upper epitaxial layer may require a level of precision that may be impractical, difficult, or costly to achieve. An attempt to grow a conformal epitaxial cladding layer on a fin is described in U.S. Patent Application Publication No. 2015/0214369 (Fronheiser). Fronheiser describes rotating a (100) substrate to form the conformal epitaxial cladding on a fin. See Fronheiser, para. [0037]. In Fronheiser, the fin is positioned in a <100> crystallographic direction of the (100) substrate. See Fronheiser, para. [0038]. The “( )” denotes a specific plane. See Fronheiser, para. [0032]. The “< >” denotes an identification of a family of equivalent directions. See Fronheiser, para. [0031].

### IV. SUMMARY

In a particular aspect, a device includes a substrate, a fin, and an isolation layer. The device also includes an epitaxial cladding layer on a sidewall of the fin. The epitaxial cladding layer has a substantially uniform thickness and has a continuous lattice structure at an interface with the sidewall. The epitaxial cladding layer is positioned above the isolation layer.

In another particular aspect, a device includes a substrate, a fin, and a planarized conformal epitaxial layer that covers an active area of the fin. The planarized conformal epitaxial layer includes a first epitaxial layer on a sidewall of the fin. The first epitaxial layer has a substantially uniform thickness and has a continuous lattice structure at an interface with the fin.

In another particular aspect, a semiconductor device includes a substrate and a fin. The semiconductor device also includes a planarized conformal epitaxial layer on a sidewall of the fin. The planarized epitaxial cladding layer has a substantially uniform thickness and has a continuous lattice structure at an interface with the sidewall.

In another particular aspect, a device includes a means for conducting charge carriers, and a means for enhancing a mobility of the charge carriers. The means for enhancing the mobility of charge carriers is positioned to conform to a shape of the means for conducting the charge carriers. At least a surface of the means for enhancing the mobility of charge carriers is planarized.

Other aspects, advantages, and features of the present disclosure will become apparent after review of the entire application, including the following sections: Brief Description of the Drawings, Detailed Description, and the Claims.

### V. BRIEF DESCRIPTION OF THE DRAWINGS

FIG. 1 is a cross-sectional view of a structure that includes a fin with an epitaxial cladding layer;

FIG. 2 is a diagram showing the crystalline structure of the fin in a cross-sectional view and a top-down view of the structure of FIG. 1;

FIG. 3 is a diagram showing a cross-sectional view of a structure formed during at least one stage of fabrication of the structure of FIG. 1;

FIG. 4 is a diagram showing a cross-sectional view of a structure formed during at least one stage of fabrication of the structure of FIG. 1;

FIG. 5 is a diagram showing a cross-sectional view of a structure formed during at least one stage of fabrication of the structure of FIG. 1;

FIG. 6 is a diagram showing a cross-sectional view of a structure formed during at least one stage of fabrication of the structure of FIG. 1;

FIG. 7 is a diagram showing a cross-sectional view of a structure formed during at least one stage of fabrication of the structure of FIG. 1;

FIG. 8 is a diagram showing a cross-sectional view of a structure formed during at least one stage of fabrication of the structure of FIG. 1;

FIG. 9 is a diagram showing a cross-sectional view of a structure formed during at least one stage of fabrication of the structure of FIG. 1;

FIG. 10 is a diagram showing a cross-sectional view of a structure formed from the structure of FIG. 1;

FIG. 11 is a diagram showing a cross-sectional view of a particular illustrative aspect of a structure that includes a fin with an epitaxial cladding layer;

FIG. 12 is a diagram showing a cross-sectional view of a structure formed during at least one stage of fabrication of the structure of FIG. 11;

FIG. 13 is a diagram showing a cross-sectional view of a structure formed during at least one stage of fabrication of the structure of FIG. 11;

FIG. 14 is a diagram showing a cross-sectional view of a structure formed during at least one stage of fabrication of the structure of FIG. 11;

FIG. 15 is a diagram showing a cross-sectional view of a structure formed during at least one stage of fabrication of the structure of FIG. 11;

FIG. 16 is a diagram showing a cross-sectional view of a structure formed during at least one stage of fabrication of the structure of FIG. 11;

FIG. 17 is a diagram showing a cross-sectional view of a structure formed during at least one stage of fabrication of the structure of FIG. 11;

FIG. 18 is a diagram showing a cross-sectional view of a structure formed during at least one stage of fabrication of the structure of FIG. 11;

FIG. 19 is a diagram showing a cross-sectional view of a structure formed from the structure of FIG. 11;

FIG. 20 is a diagram showing a cross-sectional view of a structure formed during at least one stage of fabrication of the structure of FIG. 11;

FIG. 21 is a flow chart of a particular illustrative aspect of a method of forming the structure of FIG. 1, FIG. 11, or both; and

FIG. 22 is a block diagram of an electronic device including the structure of FIG. 1, FIG. 11, or both.

### VI. DETAILED DESCRIPTION

As used herein, various terminology is for the purpose of describing particular implementations only and is not intended to be limiting of implementations. For example, the singular forms “a,” “an,” and “the” are intended to include the plural forms as well, unless the context clearly indicates otherwise. It may be further understood that the terms “comprises,” “comprised,” and “comprising” may be used interchangeably with “includes,” “included,” or “including.” Additionally, it will be understood that the term “wherein” may be used interchangeably with “where.”

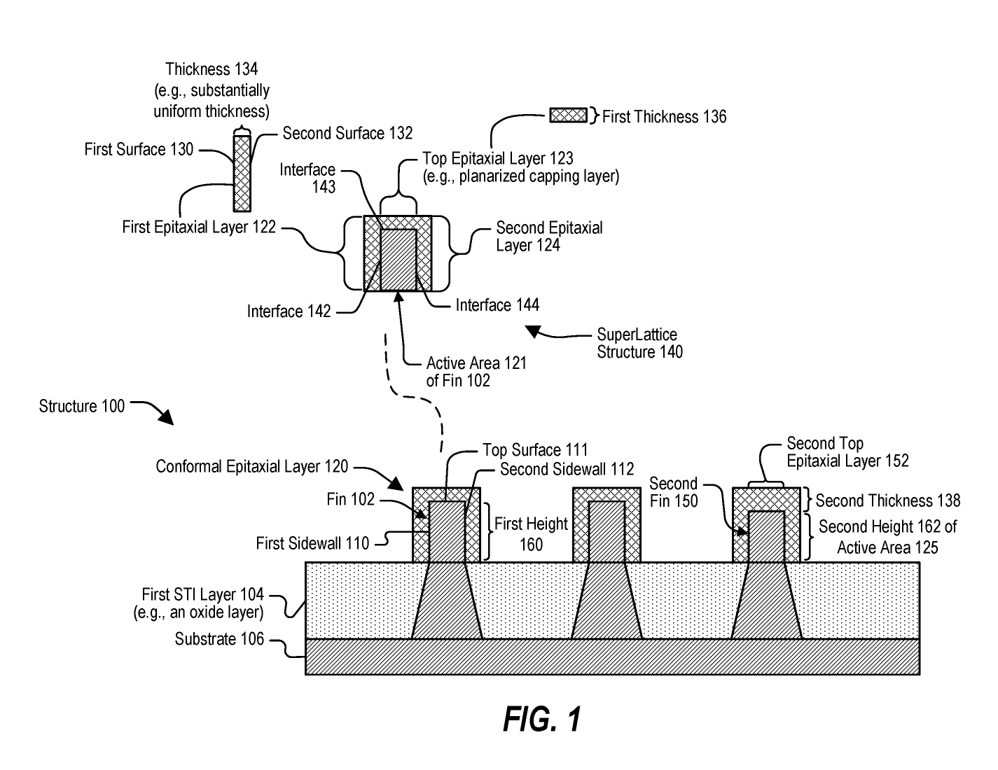

Referring to FIG. 1, a particular illustrative aspect of a structure 100 is disclosed. A device (e.g., a semiconductor device, an integrated circuit device, or another electronic device) may include the structure 100. The device may include a fin field effect transistor (finFET) device. The structure 100 includes a substrate 106. The substrate 106 may include semiconductor material, such as silicon (Si) or silicon-on-insulator (SOI), as illustrative, non-limiting examples.

The structure 100 may include one or more fins (e.g., a fin 102 and a second fin 150) overlaying the substrate 106. An active area 121 of the fin 102 may include a first sidewall 110 opposite a second sidewall 112. A top surface 111 of the fin 102 may be substantially perpendicular to the first sidewall 110, the second sidewall 112, or both. The active area 121 of the fin 102 may be covered by a conformal epitaxial layer 120. The structure 100 may include a first epitaxial layer 122 (e.g., an epitaxial cladding layer) on the first sidewall 110, a top epitaxial layer 123 (e.g., a capping layer) on the top surface 111, a second epitaxial layer 124 (e.g., a second epitaxial cladding layer) on the second sidewall 112, or a combination thereof. The first epitaxial layer 122, the top epitaxial layer 123, the second epitaxial layer 124, or a combination thereof, may correspond to a continuous epitaxial growth of the conformal epitaxial layer 120. For example, the conformal epitaxial layer 120 may include the first epitaxial layer 122, the top epitaxial layer 123, the second epitaxial layer 124, or a combination thereof.

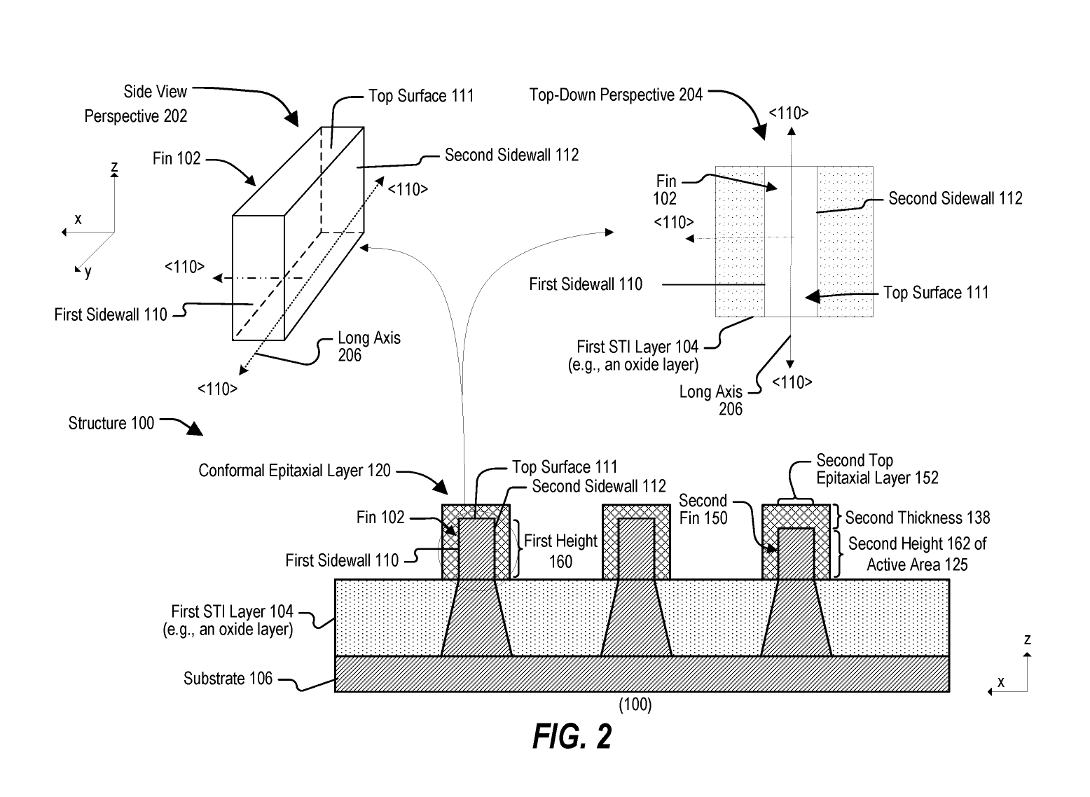

The conformal epitaxial layer 120 may have a shape corresponding to a cavity-constrained epitaxial formation. For example, the first epitaxial layer 122 may be formed in a first cavity and the second epitaxial layer 124 may be formed in a second cavity, as further described with reference to FIGS. 2-8. The cavity-constrained epitaxial formation may cause the first epitaxial layer 122, the second epitaxial layer 124, or both, to have a substantially uniform thickness, a continuous lattice structure, or both.

The first epitaxial layer 122 may include a first surface 130 opposite a second surface 132. The second surface 132 may be in contact with the first sidewall 110. A surface of the second epitaxial layer 124 may be in contact with the second sidewall 112. At least a portion of a surface of the top epitaxial layer 123 may be in contact with the top surface 111.

The conformal epitaxial layer 120 may have a continuous lattice structure at an interface with the fin 102. For example, the first epitaxial layer 122 may have a continuous lattice structure at an interface 142 with the first sidewall 110, a portion of the top epitaxial layer 123 may have a continuous lattice structure at an interface 143 with the top surface 111, the second epitaxial layer 124 may have a continuous lattice structure at an interface 144 with the second sidewall 112, or a combination thereof.

The conformal epitaxial layer 120 may correspond to a continuous epitaxial growth around one or more corners of the fin 102, such as a corner associated with an intersection of the top surface 111 and the first sidewall 110. For example, the first epitaxial layer 122 may have a continuous lattice structure with the top epitaxial layer 123. As another example, the second epitaxial layer 124 may have a continuous lattice structure with the top epitaxial layer 123.

The conformal epitaxial layer 120 (e.g., the first epitaxial layer 122, the top epitaxial layer 123, the second epitaxial layer 124, or a combination thereof) may have a substantially uniform thickness (e.g., 3 nanometers to 10 nanometers). For example, the first epitaxial layer 122 may have a thickness 134 (e.g., a substantially uniform thickness). The top epitaxial layer 123 may have a first thickness 136. The first thickness 136 may be the same as or distinct from the thickness 134. A second thickness (e.g., a substantially uniform thickness) of the second epitaxial layer 124 may be the same as or distinct from the thickness 134.

The thickness 134 may correspond to a mean free path of electron inelastic scattering. The mean free path may be determined by an electron energy loss spectroscopy (EELS) analysis of a cross-section that includes the first epitaxial layer 122 and the fin 102.

The conformal epitaxial layer 120 (e.g., the first epitaxial layer 122, the top epitaxial layer 123, the second epitaxial layer 124, or a combination thereof) may include a first material that has a greater carrier mobility than a second material (e.g., Si) of the fin 102. The conformal epitaxial layer 120 may include indium-antimony (InSb), germanium (Ge), indium-gallium-arsenide (InGaAs), or silicon germanium (SiGe). The conformal epitaxial layer 120 may include a III-V semiconductor material, a II-VI semiconductor material, or one or more other materials. The first material of the conformal epitaxial layer 120 may have a first band gap that is distinct from a second band gap of the second material of the fin 102.

The thickness 134 may be less than a critical thickness associated with formation of a layer of a superlattice structure. The cavity-constrained epitaxial formation of the first epitaxial layer 122, the second epitaxial layer 124, or both, may result in a formation of a superlattice structure 140. The superlattice structure 140 may include the active area 121 of the fin 102, the first epitaxial layer 122, the top epitaxial layer 123, the second epitaxial layer 124, or a combination thereof. For example, the first epitaxial layer 122 may correspond to a first layer of the superlattice structure 140, the active area 121 of the fin 102 may correspond to a second layer of the superlattice structure 140, and the second epitaxial layer 124 may correspond to a third layer of the superlattice structure 140. The conformal epitaxial layer 120 (e.g., the first epitaxial layer 122, the top epitaxial layer 123, the second epitaxial layer 124, or a combination thereof) may form a channel of a first material having a greater carrier mobility than the second material of the fin 102.

The structure 100 may include a first shallow trench isolation (STI) layer 104 (e.g., an oxide layer) that extends from the substrate 106 to the active area 121 of the fin 102. The first STI layer 104 may include silicon oxide (SiO), silicon oxynitride (SiON), or both, as illustrative, non-limiting examples.

An active area 125 (e.g., a second active area) of the second fin 150 may be covered by a second conformal epitaxial layer. The second conformal epitaxial layer may include a second top epitaxial layer 152 on a surface of the second fin 150 that is substantially perpendicular to a sidewall of the second fin 150. The second top epitaxial layer 152 may have a second thickness 138.

The conformal epitaxial layer 120, the second top epitaxial layer 152, or both, may be planarized (e.g., may have a planarized surface). In an example, a first epitaxial cladding layer 122 on a first sidewall 110 of the fin 102 may be planarized. In another example, the second fin 150 may include a second planarized epitaxial cladding layer on a second sidewall of the second fin 150. A first height 160 of the active area 121 may be distinct from a second height 162 of the active area 125 of the second fin 150. The first thickness 136 of the top epitaxial layer 123 may be distinct from the second thickness 138 of the second top epitaxial layer 152. Because of planarization of the conformal epitaxial layer 120 and the second top epitaxial layer 152, a first sum of the first height 160 and the first thickness 136 may be the same as a second sum of the second height 162 and the second thickness 138 so that an upper surface of the top epitaxial layer 123 is substantially aligned with an upper surface of the second top epitaxial layer 152.

The structure 100 thus has a conformal epitaxial layer on a fin having a uniform thickness and having a continuous lattice structure. The uniform thickness of the epitaxial layer may be beneficial for device performance with regard to channel control via a gate adjacent to the conformal epitaxial layer. In addition, the continuous lattice structure may be beneficial for current density due to a reduced number of defects at the interface with the fin as compared to a discontinuous lattice structure. In an implementation, the structure 100 may include an epitaxial cladding layer having a position above an isolation layer. In another implementation, the isolation layer may be above the substrate and below the planarized epitaxial cladding layer.

The structure 100 may include a gate structure (not depicted) intersecting fin 102 and fin 150. The gate structure may include a gate pad area (not depicted) at one end of the gate structure. The gate pad area may enable a voltage signal to be applied to the gate structure to enable the gate structure to modulate a current through fins 102, 150.

FIG. 2 illustrates a crystallographic direction of the fin 102 from a side view perspective 202 and a top-down perspective 204. The substrate 106 may have a (100) crystalline structure, where “( )” denotes a specific plane. For example, the crystals of the material that comprises the substrate 106 may be oriented in the x-plane of a Cartesian coordinate system. The crystals of the material comprising the first sidewall 110 of the fin 102 may be oriented in a <110> crystallographic direction, where the “< >” denotes an identification of a family of equivalent directions. For example, the crystals of the material that comprises the first sidewall 110 of the fin 102 are oriented in the x-y plane of a Cartesian coordinate system. The crystals of the material that comprises a long axis 206 of the fin 102 may be oriented in a <110> crystallographic direction. The crystals of the material that comprises a second sidewall 112 of the fin 102 may be oriented in a <110> crystallographic direction.

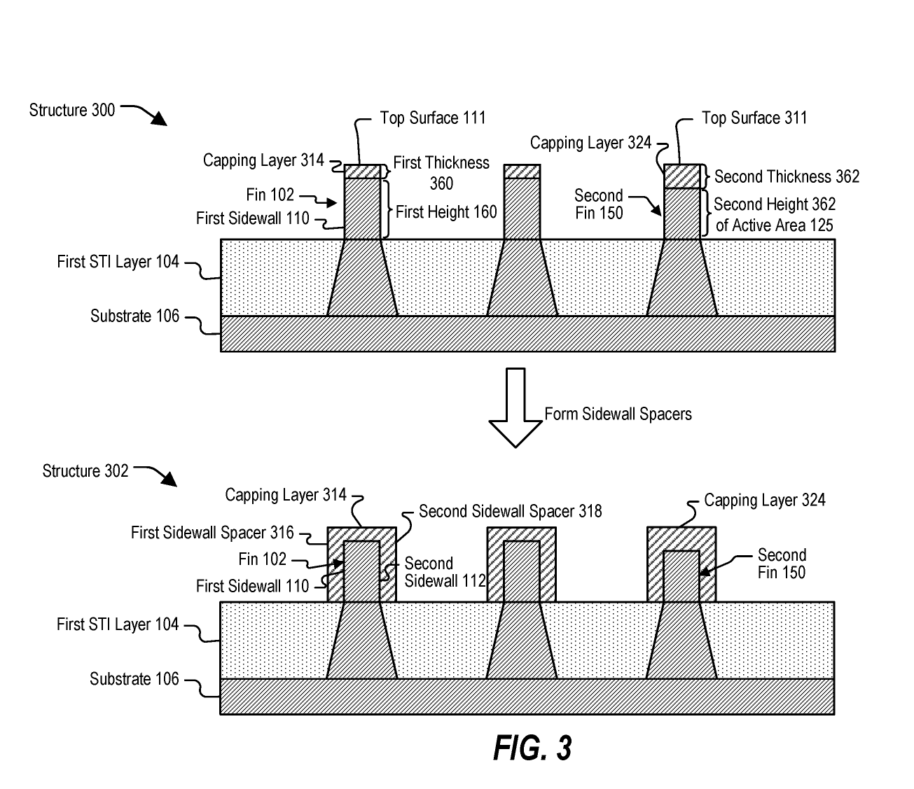

FIGS. 3-10, as described herein, illustrate a cross-sectional view of structures that may be formed during particular stages of fabrication of the structure 100 of FIG. 1. In a particular aspect, each structure illustrated in FIGS. 3-10 is formed during particular stages of fabricating an electronic device (e.g., a semiconductor device). The electronic device may include the structure 100.

Referring to FIG. 3, an illustrative diagram of a cross-sectional view of a structure 300 is shown. The structure 300 may be formed during at least one stage of fabrication of the structure 100 of FIG. 1. In a particular aspect, the structure 300 may be pre-fabricated.

The structure 300 may include the substrate 106. The structure 300 may include one or more fins (e.g., the fin 102, the second fin 150, or both) overlaying the substrate 106. In an example, the substrate 106 may be a silicon-on-insulator substrate. The active area 121 of the fin 102 may have the first height 160. The active area 125 of the second fin 150 may have the second height 162. In a particular aspect, the first height 160 may be substantially equal to the second height 162. As used herein, substantially equal may be equal or within one or more tolerances of being equal, such as being within a fabrication tolerance, a design tolerance, an operational tolerance, etc., as illustrative, non-limiting examples. In an alternate aspect, the first height 160 may be distinct from the second height 162 due to natural variations in fin heights, intentional variations in fin heights, or both.

The structure 300 may include the first STI layer 104. For example, the first STI layer 104 may extend from the substrate 106 to one or more active areas of the one or more fins (e.g., the fin 102, the second fin 150, or both). To illustrate, the first STI layer 104 may extend from the substrate 106 to the active area 121 of the fin 102. The active area 121 of the fin 102 may correspond to an exposed area of the fin 102. For example, the active area 121 of the fin 102 may correspond to an area (e.g., a surface) of the fin 102 that is not covered by the first STI layer 104.

The structure 300 may include one or more capping layers on the one or more fins. For example, the structure 300 may include a capping layer 314 on (e.g., in contact with) the top surface 111 of the fin 102, a capping layer 324 on (e.g., in contact with) a top surface 311 of the second fin 150, or both. The top surface 311 may be substantially perpendicular to a sidewall of the second fin 150. As used herein, substantially perpendicular may be perpendicular or within one or more tolerances of being perpendicular, such as being within a fabrication tolerance, a design tolerance, an operational tolerance, etc., as illustrative, non-limiting examples. The capping layer 314 may have a first thickness 360. The capping layer 324 may have a second thickness 362. In a particular aspect, the first thickness 360 may be substantially equal to the second thickness 362. In an alternate aspect, the first thickness 360 may be distinct from the second thickness 362. For example, a first sum of the first height 160 and the first thickness 360 may be substantially equal to a second sum of the second height 162 and the second thickness 362.

In a particular aspect, one or more capping layers (e.g., a hardmask layer) may be formed (e.g., deposited) on a silicon layer. For example, a capping layer 314, a capping layer 324, or both, may be formed (e.g., deposited) on the silicon layer. The one or more capping layers (e.g., the capping layer 314, the capping layer 324, or both) may cover one or more areas of a surface of the silicon layer.

Portions of the silicon layer may be removed (e.g., etched) to form a first structure including the substrate 106 and the one or more fins (e.g., the fin 102, the second fin 150, or both). For example, etching may be performed on exposed areas of the surface of the silicon layer that are not covered by the one or more capping layers (e.g., the capping layer 314 or the capping layer 324). The fin 102 may be formed under the capping layer 314. For example, the capping layer 314 may be on (e.g., in contact with) the top surface 111 of the fin 102. The second fin 150 may be formed under the capping layer 324. For example, the capping layer 324 may be on (e.g., in contact with) the top surface 311 of the second fin 150.

An STI layer (e.g., a dielectric material) may be formed (e.g., deposited or grown) on the first structure. The first STI layer 104 may be formed by removing (e.g., etching) a portion of the STI layer to expose active areas (e.g., the active area 121 of the fin 102, the active area 125 of the second fin 150, or both) of the one or more fins (e.g., the fin 102, the second fin 150, or both). The capping layer 314, the capping layer 324, or both, may include a capping material that is distinct from a material of the first STI layer 104. The capping material may include silicon nitride (SiN), another nitride, or both, as illustrative, non-limiting examples.

A structure 302 may be formed by forming sidewall spacers on the structure 300. The sidewall spacers may be formed on sidewalls of the one or more fins. For example, the structure 302 may include a first sidewall spacer 316 on (e.g., in contact with or next to) the first sidewall 110, a second sidewall spacer 318 on (e.g., in contact with or next to) the second sidewall 112, or both. In a particular aspect, a first height of the first sidewall spacer 316 (or the second sidewall spacer 318) may be substantially equal to a sum of the first height 160 of the active area 121 of the fin 102 and the first thickness 360 of the capping layer 314.

In a particular aspect, a first thickness of the first sidewall spacer 316 may be substantially equal to the thickness 134 of the first epitaxial layer 122 of FIG. 1. A second thickness of the second sidewall spacer 318 may be substantially equal to a thickness of the second epitaxial layer 124 of FIG. 1. The first thickness of the first sidewall spacer 316 may be based on an intended thickness (e.g., the thickness 134) of the first epitaxial layer 122. The intended thickness may be a default value, a user defined value, or both. Similarly, the second thickness of the second sidewall spacer 318 may be based on an intended thickness of the second epitaxial layer 124.

The first sidewall spacer 316, the second sidewall spacer 318, or both, may include a spacer material (e.g., SiN, another nitride, or both). The spacer material may be the same as or distinct from the capping material of the capping layer 314, the capping layer 324, or both. In a particular aspect, a layer of spacer material may be deposited on the structure 300. Portions of the layer of spacer material may be removed (e.g., etched) to form the sidewall spacers (e.g., the first sidewall spacer 316, the second sidewall spacer 318, or both) of the structure 302.

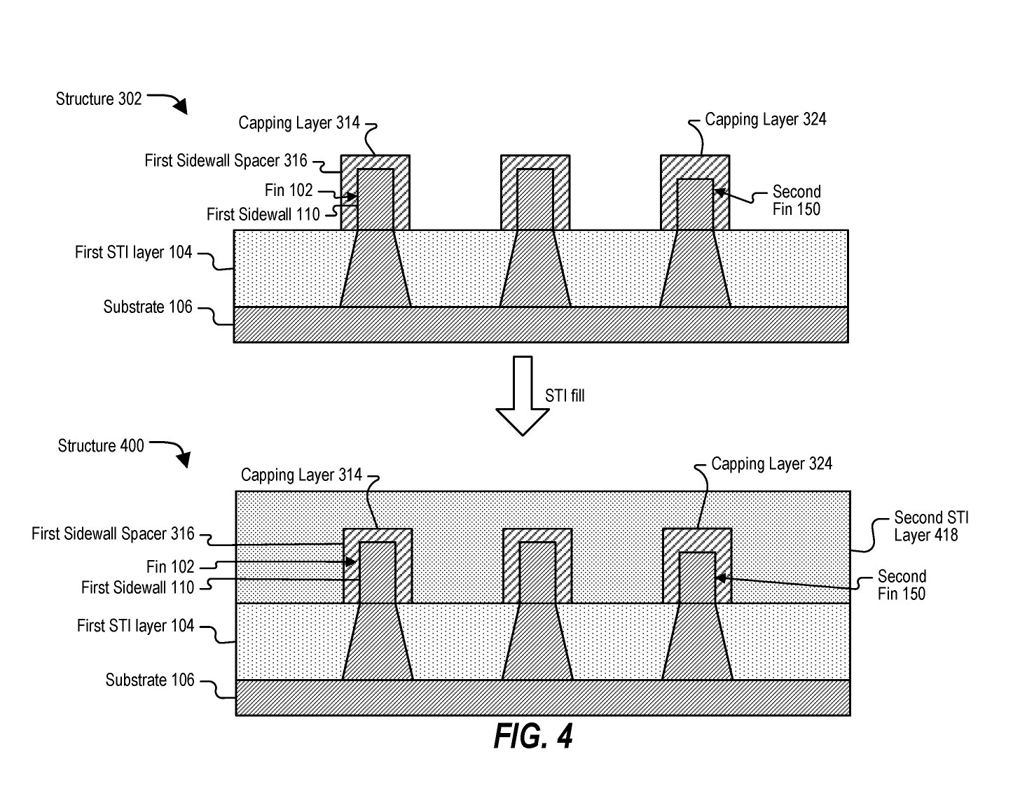

Referring to FIG. 4, an illustrative diagram of a cross-sectional view of a structure 400 is shown. The structure 400 may be formed during at least one stage of fabrication of the structure 100 of FIG. 1.

The structure 400 may be formed by performing a STI fill on the structure 302. For example, the structure 400 may be formed by depositing a second STI layer 418 (e.g., a dielectric material) on the structure 302. In a particular aspect, the second STI layer 418 may cover the capping layer 314, the capping layer 324, or both.

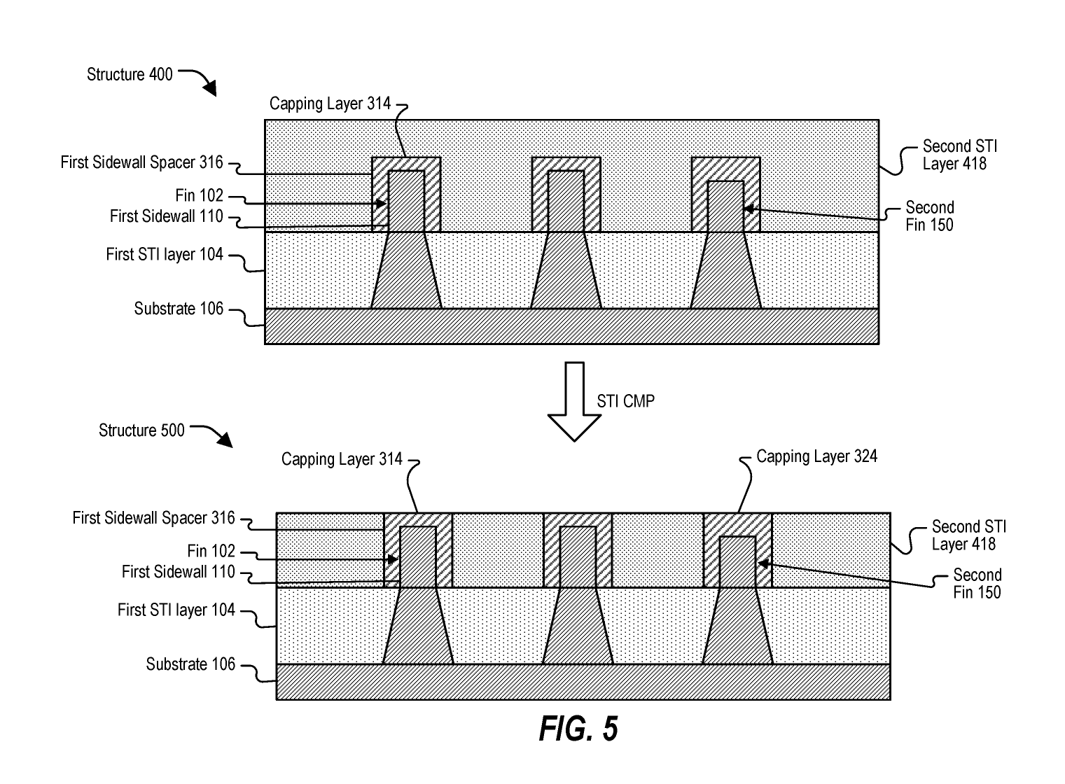

Referring to FIG. 5, an illustrative diagram of a cross-sectional view of a structure 500 is shown. The structure 500 may be formed during at least one stage of fabrication of the structure 100 of FIG. 1.

The structure 500 may be formed by performing a STI chemical-mechanical planarization (CMP) on the structure 400. For example, the structure 500 may be formed by performing CMP of the second STI layer 418 to expose a surface (e.g., a top surface) of the capping layer 314, a surface (e.g., a top surface) of the capping layer 324, or both. The top surface of the capping layer 314 may be substantially perpendicular to the first sidewall 110 of the fin 102. The top surface of the capping layer 324 may be substantially perpendicular to a sidewall of the second fin 150.

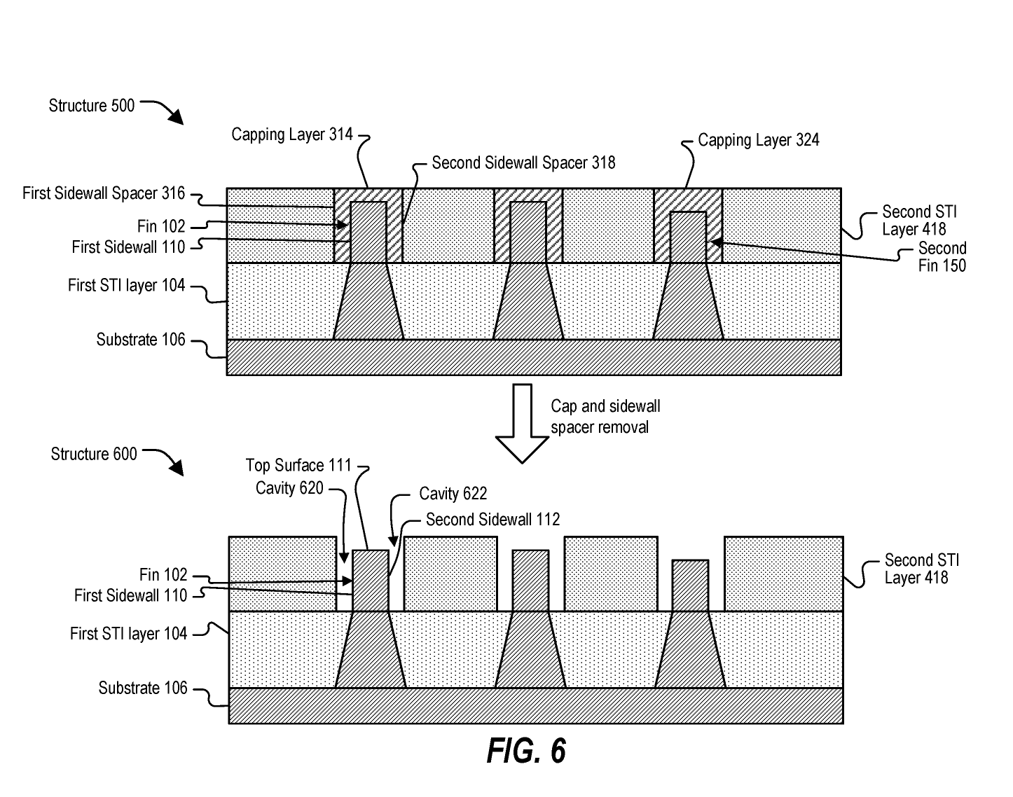

Referring to FIG. 6, an illustrative diagram of a cross-sectional view of a structure 600 is shown. The structure 600 may be formed during at least one stage of fabrication of the structure 100 of FIG. 1.

The structure 600 may be formed by removing capping layers and sidewall spacers of the structure 600. For example, the structure 600 may be formed by removing (e.g., etching) one or more capping layers and one or more sidewall spacers covering the one or more fins of the structure 500. To illustrate, the first sidewall spacer 316, the capping layer 314, and the second sidewall spacer 318 covering the fin 102 may be removed. The first sidewall spacer 316, the capping layer 314, and the second sidewall spacer 318 may be removed by performing selective etching of capping material of the capping layer 314 and spacer material of the first sidewall spacer 316 and the second sidewall spacer 318. Similarly, the capping layer 324 and sidewall spacers covering the second fin 150 may be removed (e.g., selectively etched).

Removal of the sidewall spacers may form cavities of the structure 600. For example, removal of the first sidewall spacer 316 from the structure 500 may form a cavity 620 of the structure 600. The cavity 620 may be located between a surface of the second STI layer 418 and the first sidewall 110. The cavity 620 may have a width between the surface of the second STI layer 418 and the first sidewall 110 in a range of 3 nanometers to 10 nanometers. The width of the cavity 620 may be approximately equal to a first thickness of the first sidewall spacer 316.

Removal of the second sidewall spacer 318 from the structure 600 may form a cavity 622 of the structure 600. The cavity 622 may be located between a surface of the second STI layer 418 and the second sidewall 112. The cavity 622 may have a width between the surface of the second STI layer 418 and the second sidewall 112 in a range of 3 nanometers to 10 nanometers. The width of the cavity 622 may be approximately equal to a second thickness of the second sidewall spacer 318.

Removal of the capping layers may expose top surfaces of the one or more fins. For example, removal of the capping layer 314 may expose the top surface 111 of the fin 102.

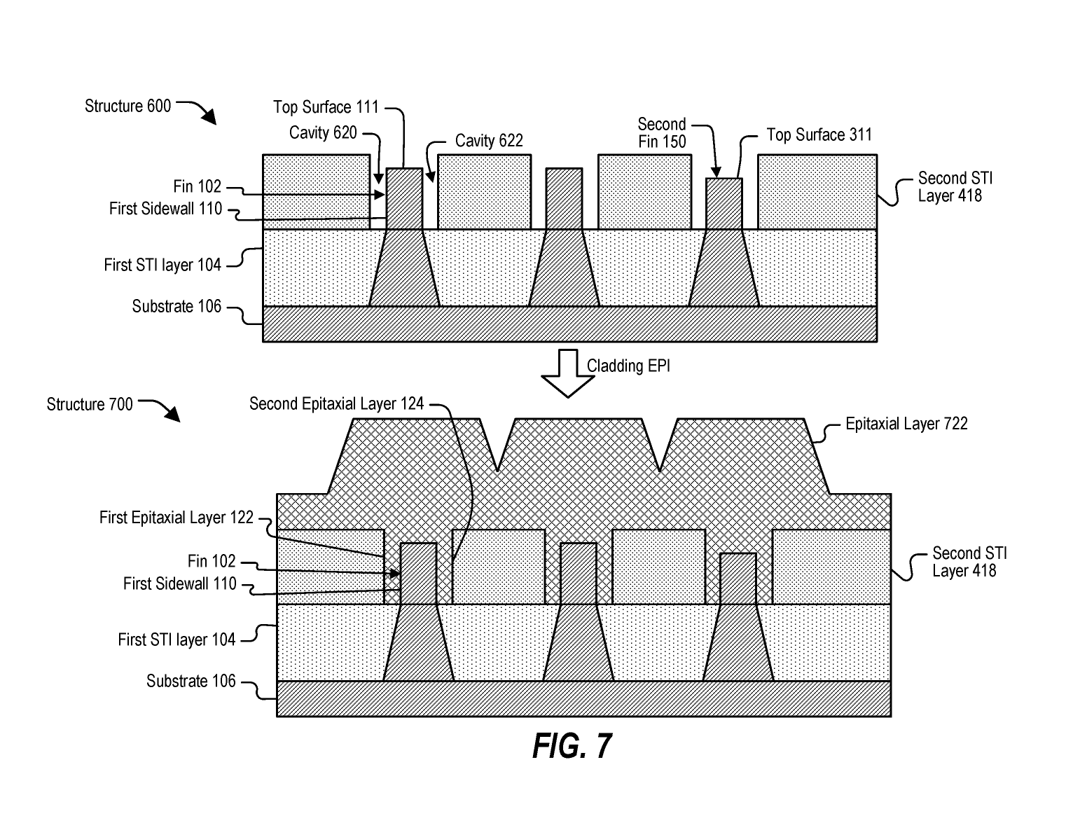

Referring to FIG. 7, an illustrative diagram of a cross-sectional view of a structure 700 is shown. The structure 700 may be formed during at least one stage of fabrication of the structure 100 of FIG. 1.

The structure 700 may be formed by performing epitaxial growth of a cladding layer on the structure 600. For example, an epitaxial layer 722 may be grown on the structure 600. The epitaxial layer 722 may fill spaces between the active areas of the fins (e.g., the active area 121 of the fin 102) and the second STI layer 418. For example, the epitaxial layer 722 may fill the cavity 620, the cavity 622, or both. To illustrate, the epitaxial layer 722 may include the first epitaxial layer 122 formed in the cavity 620 between a surface of the second STI layer 418 and the first sidewall 110. The epitaxial layer 722 may include the second epitaxial layer 124 formed in the cavity 622 between a surface of the second STI layer 418 and the second sidewall 112.

The epitaxial layer 722 may cover a top surface of the second STI layer 418 and top surfaces of the fins. For example, the epitaxial layer 722 may cover the top surface 111 of the fin 102, the top surface 311 of the second fin 150, or both. The top surface of the second STI layer 418 and the top surfaces (e.g., the top surface 111, the top surface 311, or both) of the fins may be substantially perpendicular to the first sidewall 110.

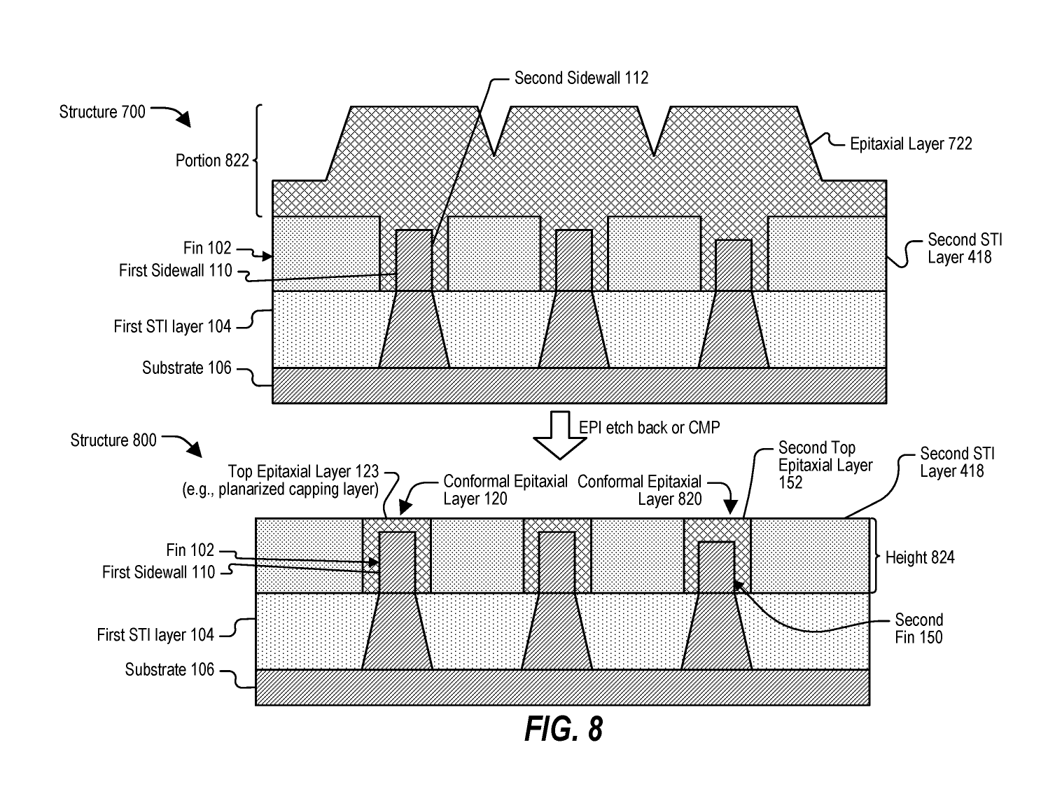

Referring to FIG. 8, an illustrative diagram of a cross-sectional view of a structure 800 is shown. The structure 800 may be formed during at least one stage of fabrication of the structure 100 of FIG. 1.

The structure 800 may be formed by performing epitaxial (EPI) etch back or CMP on the epitaxial layer 722 of the structure 700. For example, a portion 822 of the epitaxial layer 722 may be removed by performing EPI etch back, CMP, or both, to expose a top surface of the second STI layer 418. The top surface of the second STI layer 418 may be substantially perpendicular to the first sidewall 110.

One or more remaining portions of the epitaxial layer 722 may cover the one or more fins of the structure 800. For example, the conformal epitaxial layer 120 may cover the fin 102. The conformal epitaxial layer 120 may include the top epitaxial layer 123. As another example, a second conformal epitaxial layer 820 may cover the second fin 150. The second conformal epitaxial layer 820 may include the second top epitaxial layer 152. The top epitaxial layer 123, the second top epitaxial layer 152, or both, may be etched or planarized capping layers. A first sum of the first height 160 of FIG. 1 and the first thickness 136 of the top epitaxial layer 123, a second sum of the second height 162 of FIG. 1 and the second thickness 138 of the second top epitaxial layer 152, or both, may be substantially equal to a height 824 of the second STI layer 418 after planarization or EPI etch back.

A top surface of the first epitaxial layer 122, a top surface of the second epitaxial layer 124, or both, may be etched or planarized. The top surface of the first epitaxial layer 122, the top surface of the second epitaxial layer 124, or both, may be substantially perpendicular to the first sidewall 110.

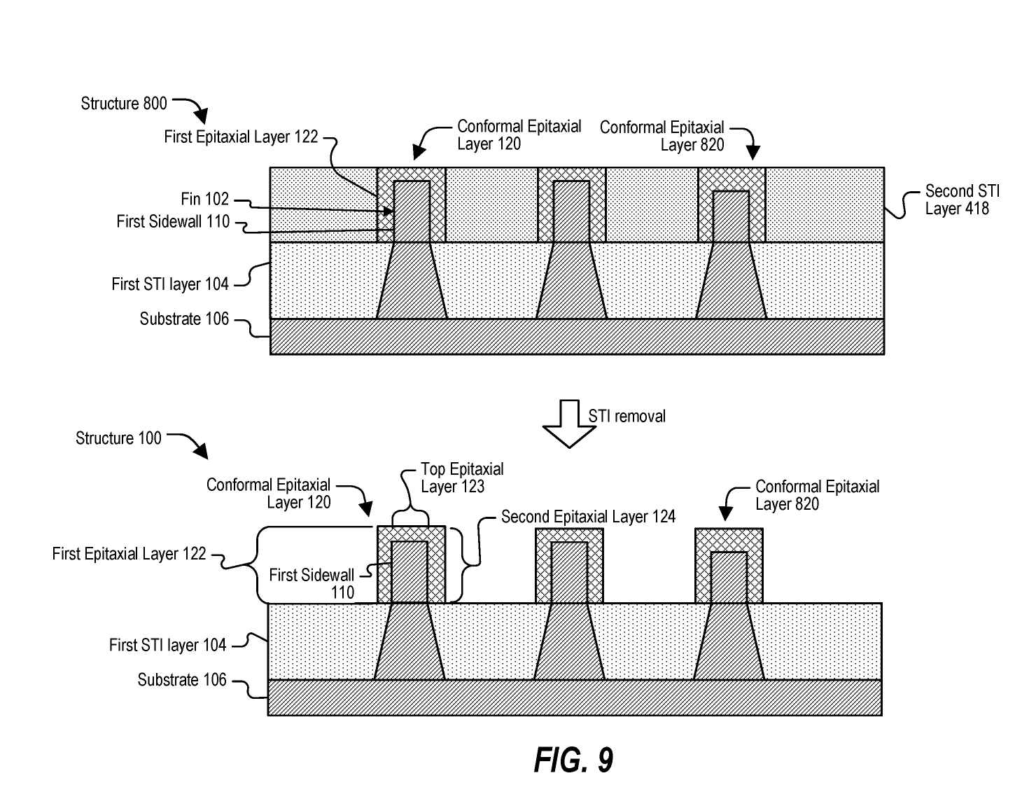

Referring to FIG. 9, an illustrative diagram of a cross-sectional view of the structure 100 is shown. The structure 100 may be formed by performing STI removal on the structure 800. For example, the second STI layer 418 may be removed using an etchant (e.g., an acid solution) that selectively removes material of the second STI layer 418. To illustrate, the etchant may be non-reactive with a material of the conformal epitaxial layer 120, a material of the second conformal epitaxial layer 820, a material of the first STI layer 104, or a combination thereof.

Removing the second STI layer 418 may expose one or more surfaces of the conformal epitaxial layer 120, the second conformal epitaxial layer 820, or both. For example, removing the second STI layer 418 may expose the first epitaxial layer 122, the second epitaxial layer 124, or both.

In a particular aspect, an oxide layer may be formed by oxidizing a conformal epitaxial layer (e.g., the conformal epitaxial layer 120, the second conformal epitaxial layer 820, or both). For example, the oxide layer may include a silicon oxide (SiO) layer. The oxide layer may be removed (e.g., etched). To illustrate, the SiO layer may be removed by an etch process. Forming the oxide layer may increase a concentration of a first material (e.g., germanium) in the conformal epitaxial layer (e.g., the conformal epitaxial layer 120, the second conformal epitaxial layer 820, or both). For example, the conformal epitaxial layer (e.g., the conformal epitaxial layer 120, the second conformal epitaxial layer 820, or both) may include a combination (e.g., SiGe) of the first material (e.g., germanium) and a second material (e.g., Si). Forming the oxide layer may use (e.g., oxidize) some of the second material (e.g., Si), leaving a higher concentration of the first material (e.g., germanium) in the conformal epitaxial layer (e.g., the conformal epitaxial layer 120, the second conformal epitaxial layer 820, or both).

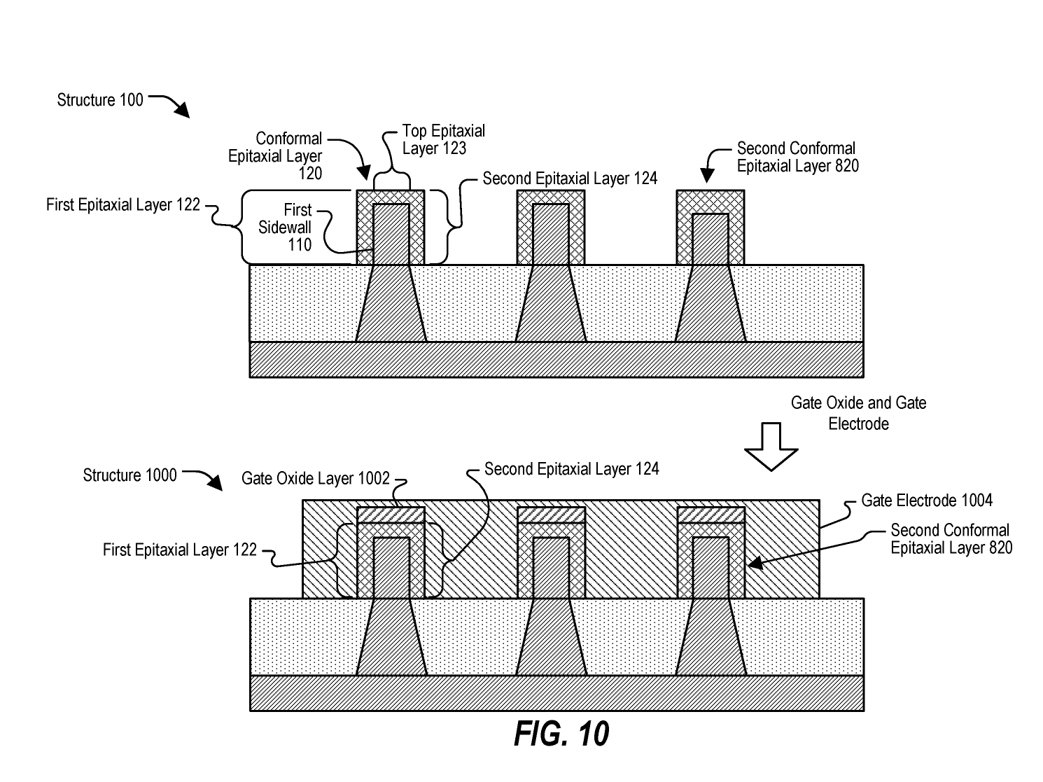

Referring to FIG. 10, an illustrative diagram of a cross-sectional view of a structure 1000 is shown. The structure 1000 may be fabricated from the structure 100. For example, the structure 1000 may be fabricated by forming a gate oxide layer 1002 on the top epitaxial layer 123. The gate oxide layer 1002 may be formed by oxidizing the top epitaxial layer 123. A gate electrode 1004 may be deposited over the gate oxide layer 1002. The gate electrode 1004 may be fabricated from any of aluminum, doped silicon, a refractory metal, or a combination of these. In some implementations, a refractory metal can be any of tungsten or a silicide, such as titanium silicide (TiSi), molybdenum silicide (MoSi₂), tantalum silicide (TaSi), tungsten silicide (WSi₂), or a combination thereof, as illustrative, non-limiting examples.

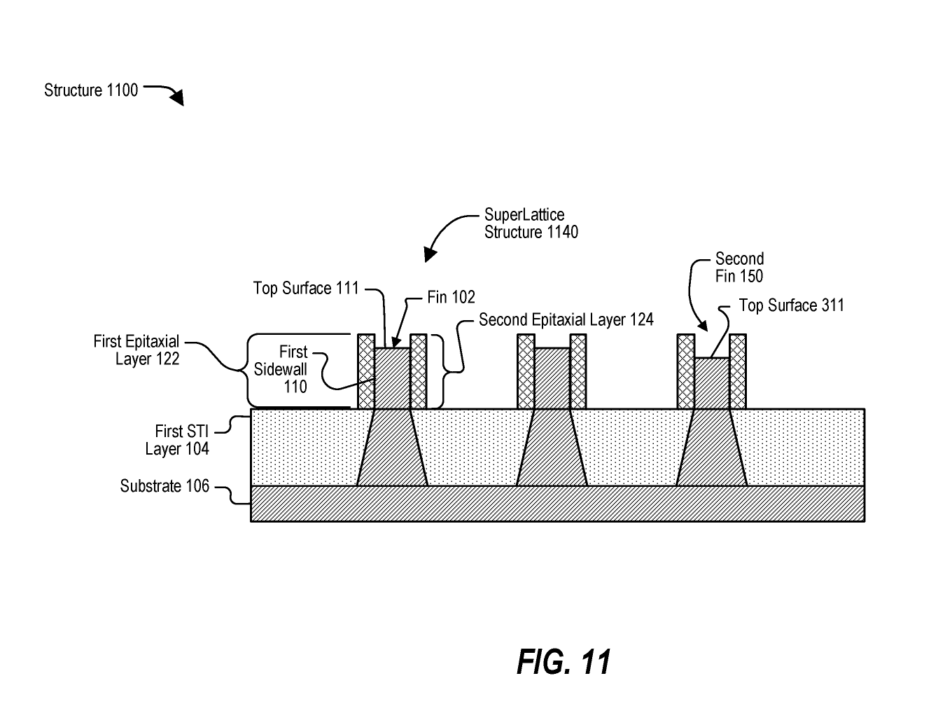

Referring to FIG. 11, an illustrative diagram of a cross-sectional view of a structure 1100 is shown. The structure 1100 differs from the structure 100 of FIG. 1 in that an epitaxial cladding layer may be absent from a top surface of one or more fins. For example, the top epitaxial layer 123, the second top epitaxial layer 152, or both, may be absent from the structure 1100. A top surface of one or more fins may be exposed. For example, the top surface 111, the top surface 311, or both, may be exposed.

The structure 1100 may include the first epitaxial layer 122, the fin 102, and the second epitaxial layer 124. The first epitaxial layer 122, the fin 102, and the second epitaxial layer 124 may form a superlattice structure 1140.

The structure 1100 has a conformal epitaxial layer (e.g., the first epitaxial layer 122, the second epitaxial layer 124, or both) on a fin having a uniform thickness and having a continuous lattice structure. The uniform thickness and/or the continuous lattice structure of the epitaxial layer may be beneficial for device performance.

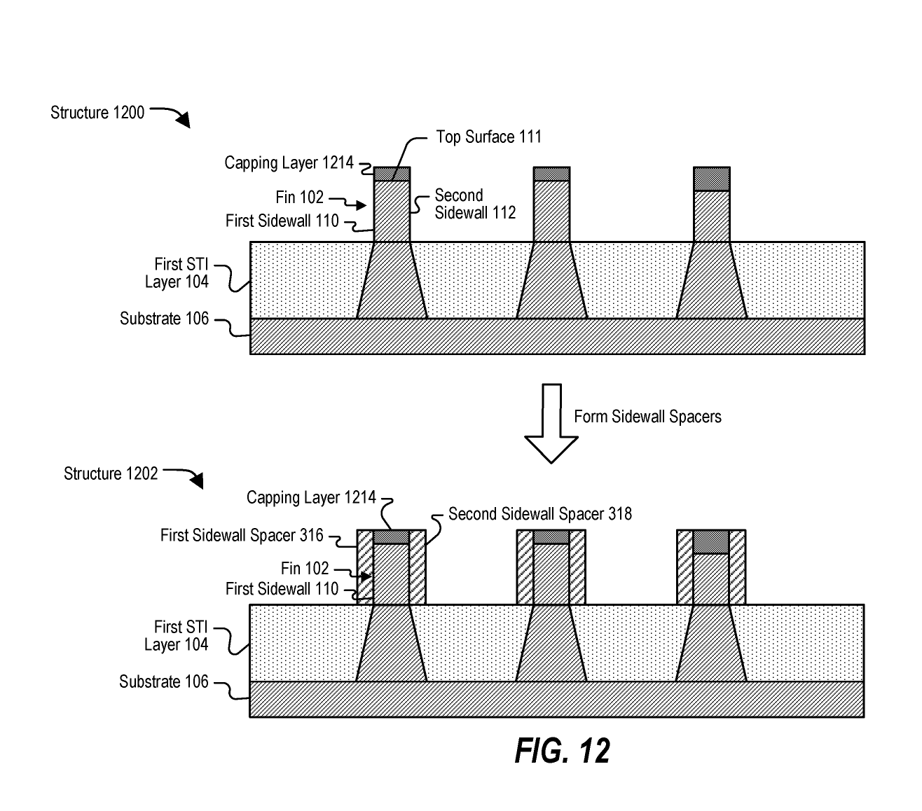

FIGS. 12-20, as described herein, illustrate cross-sectional view of structures formed during particular stages of fabrication of the structure 1100 of FIG. 11. In a particular aspect, each structure illustrated in FIGS. 12-20 is formed during particular stages of fabricating an electronic device (e.g., a semiconductor device). The electronic device may include the structure 1100.

Referring to FIG. 12, an illustrative diagram of a cross-sectional view of a structure 1200 is shown. The structure 1200 may be formed during at least one stage of fabrication of the structure 1100 of FIG. 11.

The structure 1200 may differ from the structure 300 of FIG. 3 in that a capping layer 1214 on (e.g., in contact with) the top surface 111 of the fin 102 may include a first capping material (e.g., a nitride) that is distinct from a second capping material of the capping layer 314 of FIG. 3. The first capping material may be distinct from a spacer material of the first sidewall spacer 316. The second capping material may be the same as the spacer material.

The structure 1202 may be formed by forming sidewall spacers on one or more fins of the structure 1200. For example, the first sidewall spacer 316 may be formed on the first sidewall 110 of the fin 102, the second sidewall spacer 318 may be formed on the second sidewall 112, or both, as described with reference to FIG. 3.

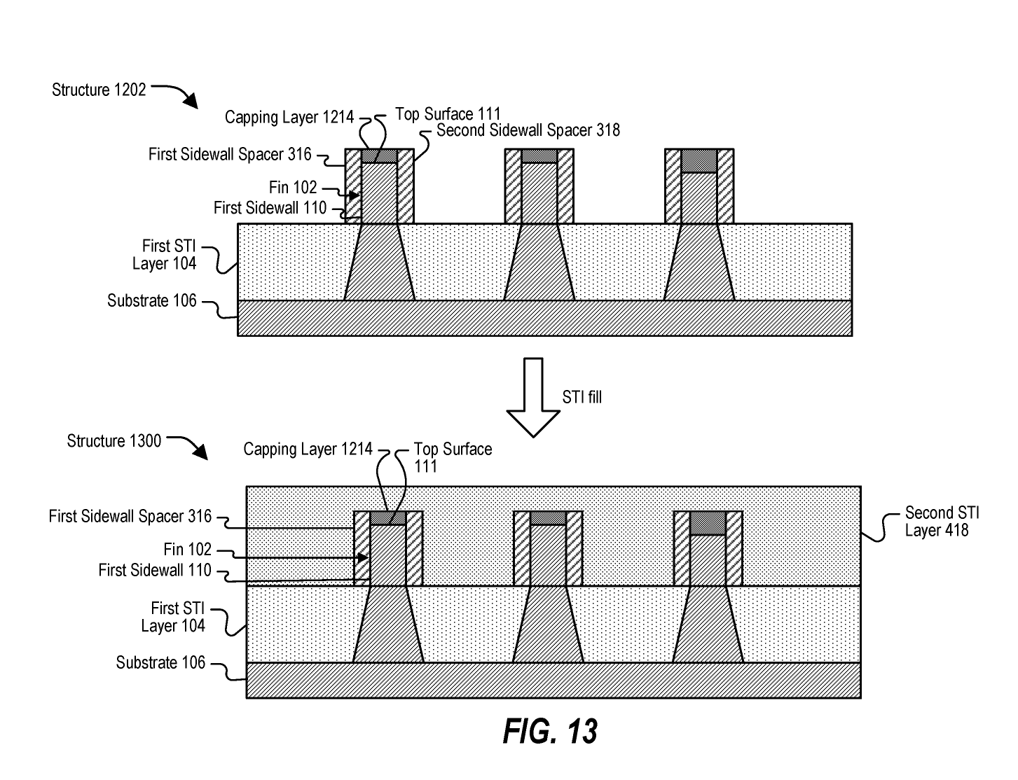

Referring to FIG. 13, an illustrative diagram of a cross-sectional view of a structure 1300 is shown. The structure 1300 may be formed during at least one stage of fabrication of the structure 1100 of FIG. 11.

The structure 1300 may be formed by performing a STI fill on the structure 1202. For example, the second STI layer 418 may be formed, as described with reference to FIG. 4. The second STI layer 418 may cover the capping layers (e.g., the capping layer 1214) and the sidewall spacers (e.g., the first sidewall spacer 316, the second sidewall spacer 318, or both).

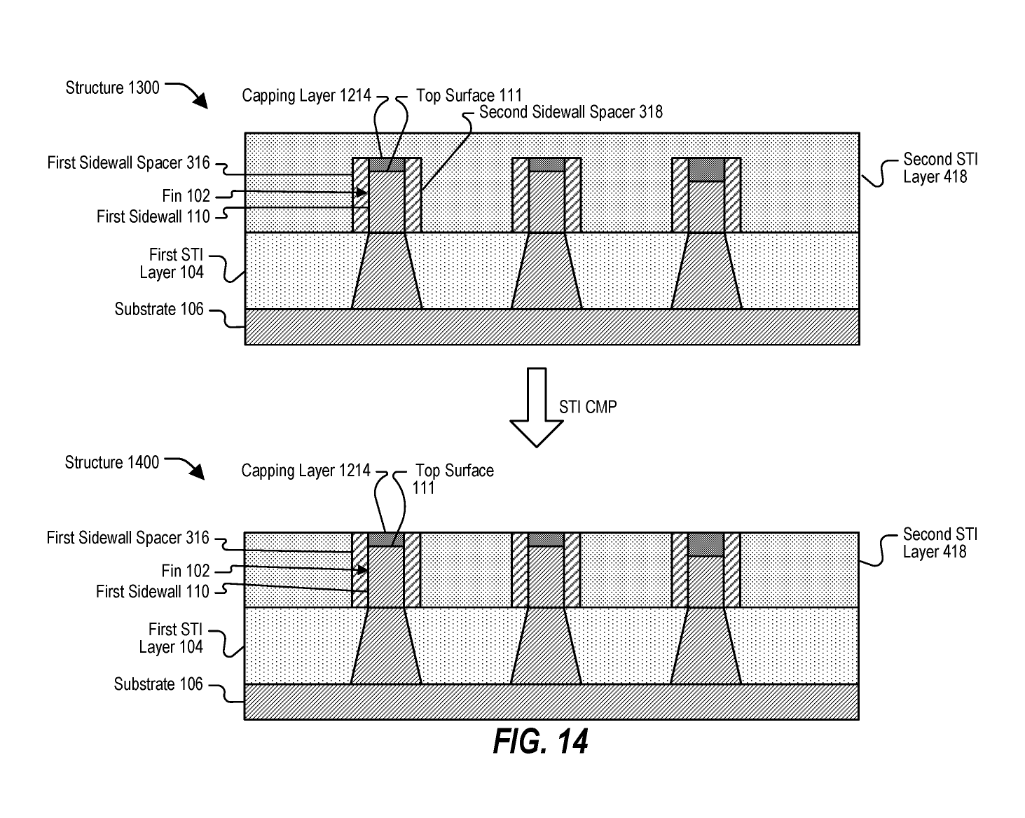

Referring to FIG. 14, an illustrative diagram of a cross-sectional view of a structure 1400 is shown. The structure 1400 may be formed during at least one stage of fabrication of the structure 1100 of FIG. 11.

The structure 1400 may be formed by performing a STI CMP on the structure 1300. For example, the second STI layer 418 may be formed, as described with reference to FIG. 4. The second STI layer 418 may be formed by planarizing the second STI layer 418 to expose top surfaces of sidewall spacers and capping layers. For example, the second STI layer 418 may be planarized to expose a top surface of the first sidewall spacer 316, a top surface of the capping layer 1114, a top surface of the second sidewall spacer 318, or a combination thereof. The first sidewall 110 may be substantially perpendicular to the top surface of the first sidewall spacer 316, the top surface of the capping layer 1114, the top surface of the second sidewall spacer 318, or a combination thereof.

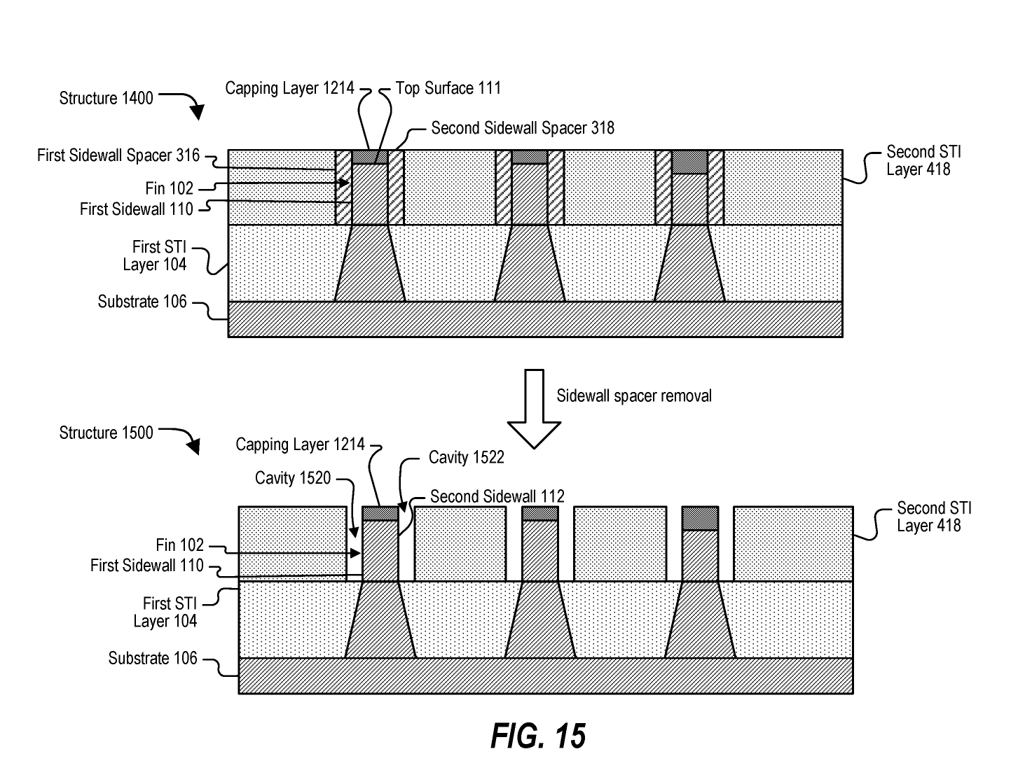

Referring to FIG. 15, an illustrative diagram of a cross-sectional view of a structure 1500 is shown. The structure 1500 may be formed during at least one stage of fabrication of the structure 1100 of FIG. 11.

The structure 1500 may be formed by performing sidewall spacer removal on the structure 1400. For example, the first sidewall spacer 316, the second sidewall spacer 318, or both, may be removed, as described with reference to FIG. 6. The sidewall spacers may be etched using an etchant that is selective to remove the spacer material. For example, the etchant may be non-reactive to a capping material of the capping layer 1214. Removing the first sidewall spacer 316 may form a cavity 1520 of the structure 1400 between a surface of the second STI layer 418 and the first sidewall 110 and between the surface of the second STI layer 418 and a first side surface of the capping layer 1214. The first side surface of the capping layer 1214 may be substantially parallel to the first sidewall 110. As used herein, substantially parallel may be parallel or within one or more tolerances of being parallel, such as being within a fabrication tolerance, a design tolerance, operational tolerance, etc., as illustrative, non-limiting examples. The first side surface may be co-planar to the first sidewall 110. The cavity 1520 may have a width between the surface of the second STI layer 418 and the first sidewall 110 (or the first side surface of the capping layer 1214) in a range of 3 nanometers to 10 nanometers. The width of the cavity 1520 may be approximately equal to a first thickness of the first sidewall spacer 316.

Removing the second sidewall spacer 318 may form a cavity 1522 of the structure 1400 between a surface of the second STI layer 418 and the second sidewall 112 and between the surface of the second STI layer 418 and a second side surface of the capping layer 1114. The second side surface of the capping layer 1114 may be substantially parallel to the second sidewall 112. The second side surface may be co-planar to the second sidewall 112. The cavity 1522 may have a width between the surface of the second STI layer 418 and the second sidewall 112 (or the second side surface of the capping layer 1214) in a range of 3 nanometers to 10 nanometers. The width of the cavity 1522 may be approximately equal to a second thickness of the second sidewall spacer 318.

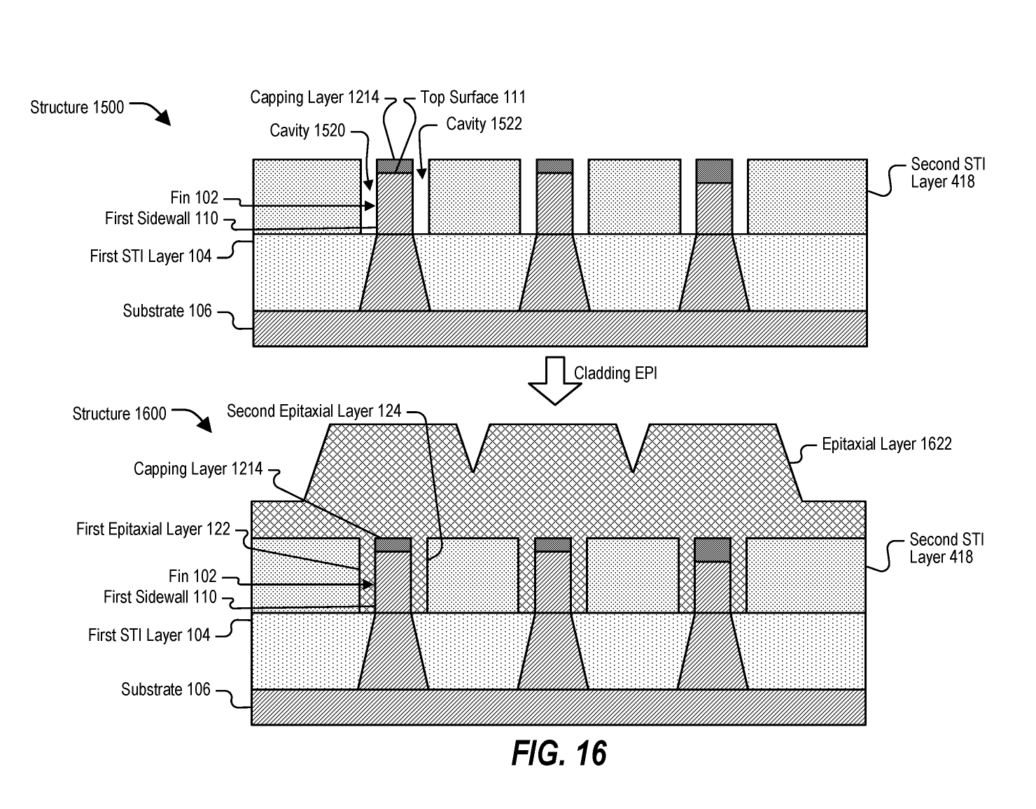

Referring to FIG. 16, an illustrative diagram of a cross-sectional view of a structure 1600 is shown. The structure 1600 may be formed during at least one stage of fabrication of the structure 1100 of FIG. 11.

The structure 1600 may be formed by performing epitaxial growth of a cladding layer on the structure 1500. For example, an epitaxial layer 1622 may be grown on the structure 1500. The epitaxial layer 1622 may fill cavities of the structure 1500. For example, the epitaxial layer 1622 may fill the cavity 1520, the cavity 1522, or both. To illustrate, the epitaxial layer 1622 may include the first epitaxial layer 122 formed in the cavity 1520. The epitaxial layer 1622 may include the second epitaxial layer 124 formed in the cavity 1522.

The epitaxial layer 1622 may cover a top surface of the second STI layer 418 and top surfaces of the capping layers. For example, the epitaxial layer 1622 may cover a top surface of the capping layer 1214. The top surface of the second STI layer 418, the top surface of the capping layer 1214, or both, may be substantially perpendicular to the first sidewall 110.

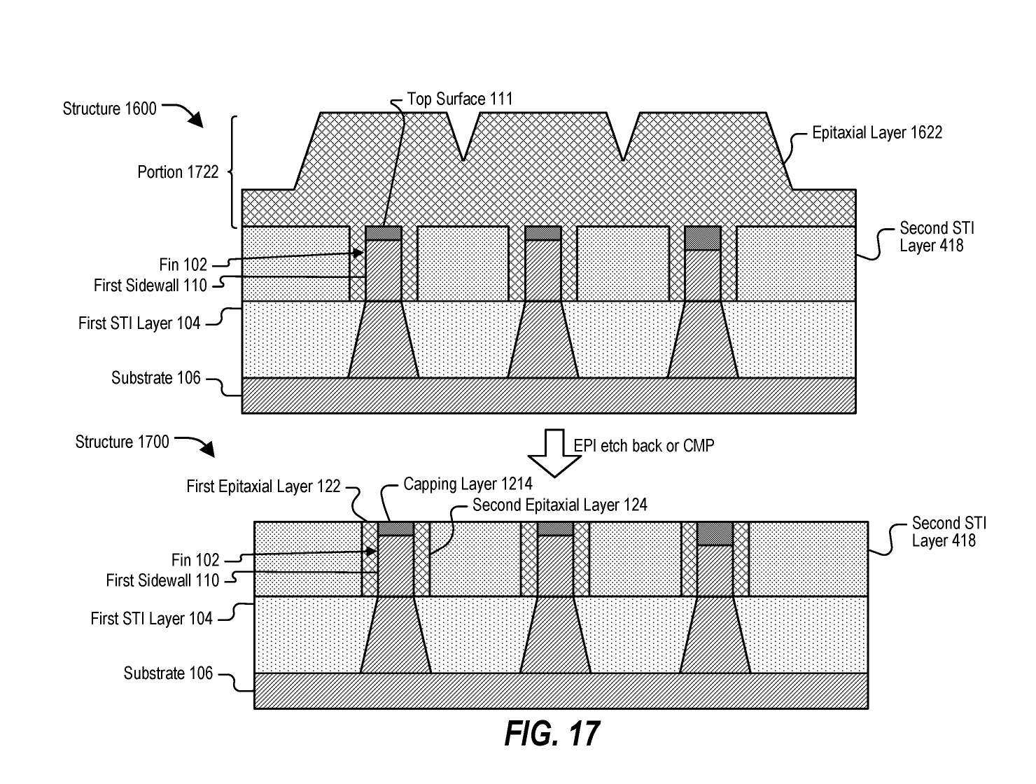

Referring to FIG. 17, an illustrative diagram of a cross-sectional view of a structure 1700 is shown. The structure 1700 may be formed during at least one stage of fabrication of the structure 1100 of FIG. 11.

The structure 1700 may be formed by performing an epitaxial etch back or CMP on the epitaxial layer 1622 of the structure 1600. For example, a portion 1722 of the epitaxial layer 1622 may be removed by performing EPI etch back, CMP, or both, to expose a top surface of the second STI layer 418. The top surface of the second STI layer 418 may be substantially perpendicular to the first sidewall 110.

One or more portions of the epitaxial layer 1622 on sidewalls of fins of the structure 1600 may remain subsequent to the EPI etch back or CMP. For example, the structure 1700 may include the first epitaxial layer 122, the second epitaxial layer 124, or both. A top surface of the first epitaxial layer 122, a top surface of the second epitaxial layer 124, or both, may be etched or planarized. The top surface of the first epitaxial layer 122, the top surface of the second epitaxial layer 124, or both, may be substantially perpendicular to the first sidewall 110.

The first epitaxial layer 122 may have a first height from the first STI layer 104 to the top surface of the first epitaxial layer 122. The first height may be approximately equal to a second height of another epitaxial layer on another fin (e.g., the second fin 150).

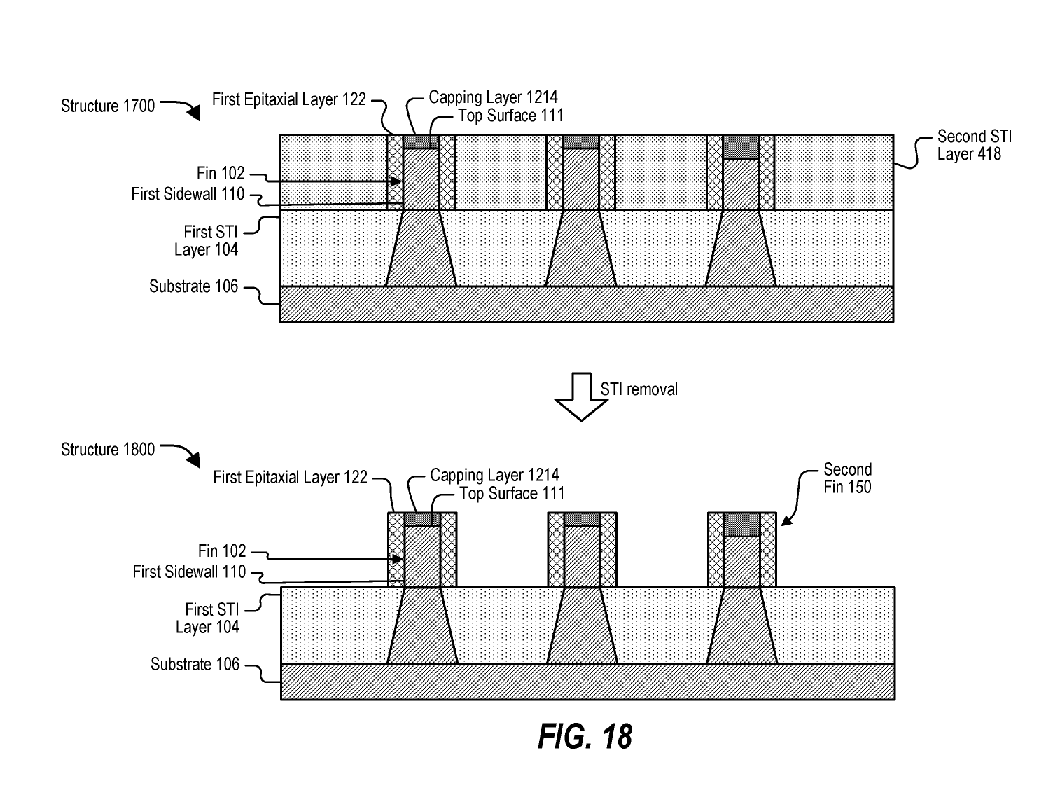

Referring to FIG. 18, an illustrative diagram of a cross-sectional view of a structure 1800 is shown. The structure 1800 may be formed during at least one stage of fabrication of the structure 1100 of FIG. 11.

The structure 1800 may be formed by performing STI removal on the structure 1700. For example, the second STI layer 418 may be removed, as described with reference to FIG. 9.

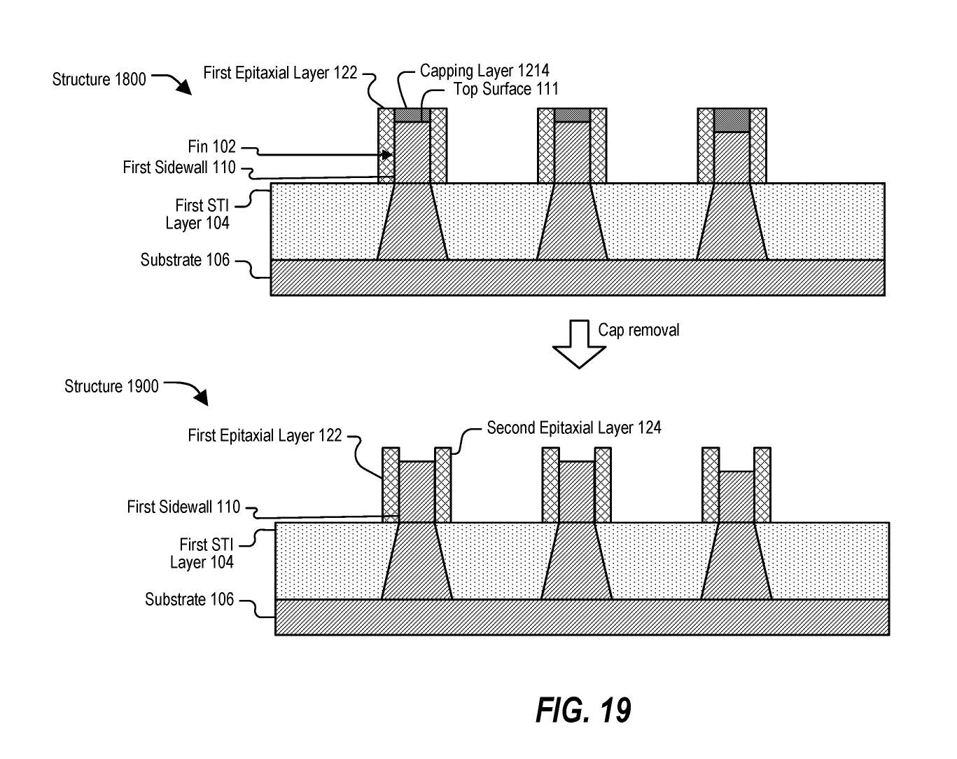

Referring to FIG. 19, an illustrative diagram of a cross-sectional view of the structure 1100 is shown. The structure 1100 may be formed by performing cap removal on the structure 1800. For example, capping layers (e.g., the capping layer 1214) on the fins (e.g., the fin 102) of the structure 1800 may be removed (e.g., etched) to form the structure 1100.

In a particular aspect, an oxide (e.g., silicon oxide (SiO)) layer may be formed by oxidizing a conformal epitaxial layer (e.g., the first epitaxial layer 122, the second epitaxial layer 124, or both). The oxide layer may be removed (e.g., etched).

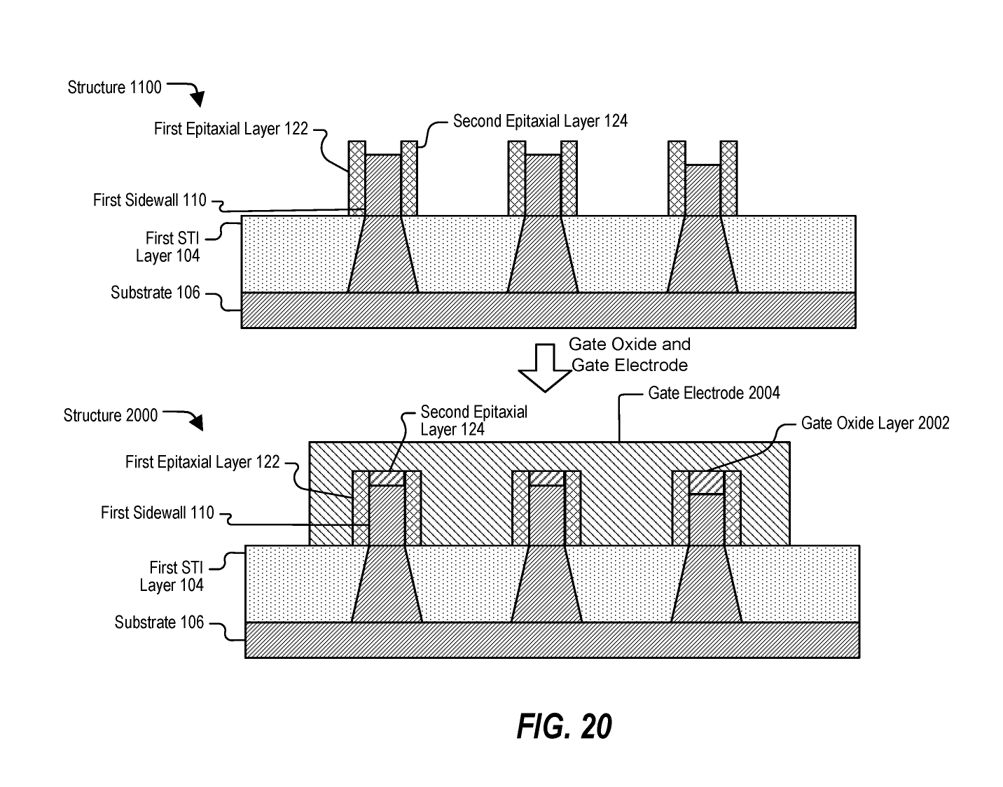

Referring to FIG. 20, a cross sectional view of a structure 2000 is shown. The structure 2000 may be fabricated from the structure 1100. For example, the structure 2000 may be fabricated by forming a gate oxide layer 2002 on the top surface 111. The gate oxide layer 2002 may be formed by oxidizing the silicon of the top surface 111. A gate electrode 2004 may be formed over the gate oxide layer 2002. The gate electrode 1004 may be formed from any of aluminum, doped silicon, a refractory metal, or a combination of these. A refractory metal can be any of tungsten or a silicide, such as titanium silicide (TiSi), molybdenum silicide (MoSi₂), tantalum silicide (TaSi), tungsten silicide (WSi₂), or a combination thereof, as illustrative, non-limiting examples.

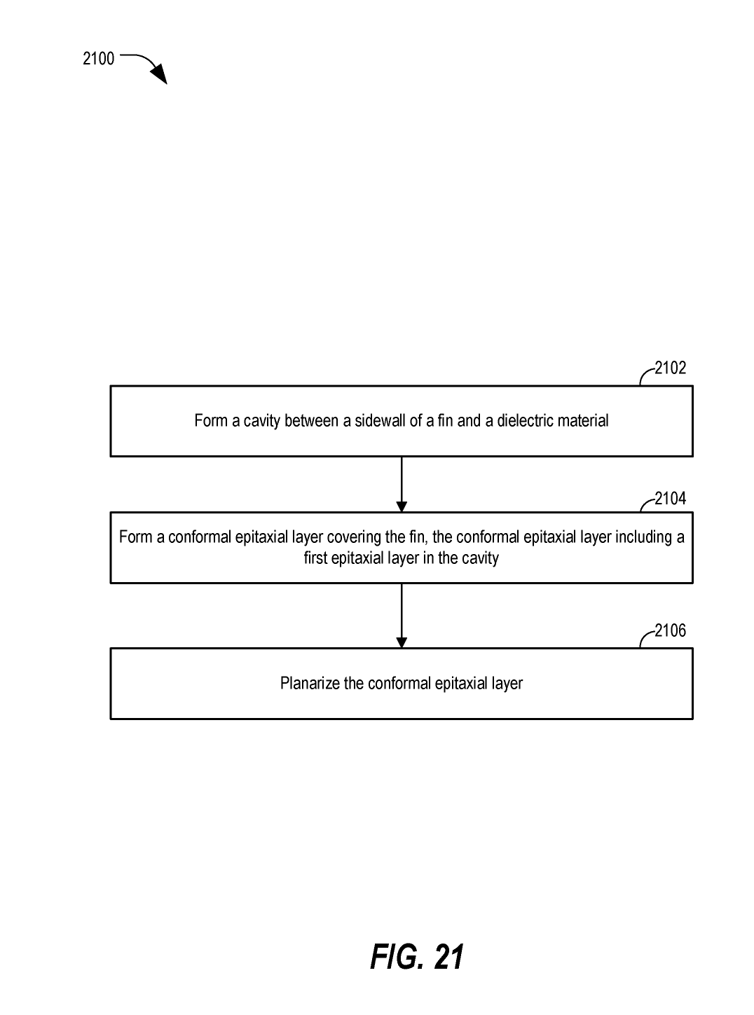

FIG. 21 is a flow chart illustrating an aspect of a method of forming the structure 100 of FIG. 1, the structure 1100 of FIG. 11, or both. The structure may be included in a device, such as a finFET device. The method 2100 includes forming a cavity between a sidewall of a fin and a dielectric material, at 2102. For example, the structure 100 of FIG. 1 may be formed by forming the cavity 620, the cavity 622 of FIG. 6, or both, as described with reference to FIG. 6. The cavity 620 may be formed between the first sidewall 110 and the second STI layer 418 (e.g., a dielectric material). The cavity 622 may be formed between the second sidewall 112 and the second STI layer 418 (e.g., a dielectric material).

As another example, the structure 1100 of FIG. 11 may be formed by forming the cavity 1520, the cavity 1522 of FIG. 15, or both, as described with reference to FIG. 15. The cavity 1520 may be formed between the first sidewall 110 and the second STI layer 418 (e.g., a dielectric material). The cavity 1522 may be formed between the second sidewall 112 and the second STI layer 418 (e.g., a dielectric material).

The method 2100 also includes forming a conformal epitaxial layer covering the fin, at 2104. For example, the structure 100 of FIG. 1 may be formed by forming the epitaxial layer 722 of FIG. 7 (e.g., a conformal epitaxial layer) covering the fin 102, as described with reference to FIG. 7. The epitaxial layer 722 may include the first epitaxial layer 122 in the cavity 620. The epitaxial layer 722 may include the second epitaxial layer 124 in the cavity 622.

As another example, the structure 1100 of FIG. 11 may be formed by forming the epitaxial layer 1622 of FIG. 16 (e.g., a conformal epitaxial layer) covering the fin 102, as described with reference to FIG. 16. The epitaxial layer 1622 may include the first epitaxial layer 122 in the cavity 1520. The epitaxial layer 1622 may include the second epitaxial layer 124 in the cavity 1522.

The method 2100 further includes planarizing the conformal epitaxial layer, at 2106. For example, forming the structure 100 of FIG. 1 may include planarizing the epitaxial layer 722, as described with reference to FIG. 8. As another example, forming the structure 1100 of FIG. 11 may include planarizing the epitaxial layer 1622, as described with reference to FIG. 17.

The method 2100 may thus enable forming a structure (e.g., the structure 100 of FIG. 1, the structure 1100 of FIG. 11, or both) with an epitaxial layer on a sidewall of a fin. For example, in a particular implementation, a semiconductor device may be formed that includes the structure 100 of FIG. 1 and the structure 1100 of FIG. 11 on the same substrate. A surface of the epitaxial layer may be planarized.

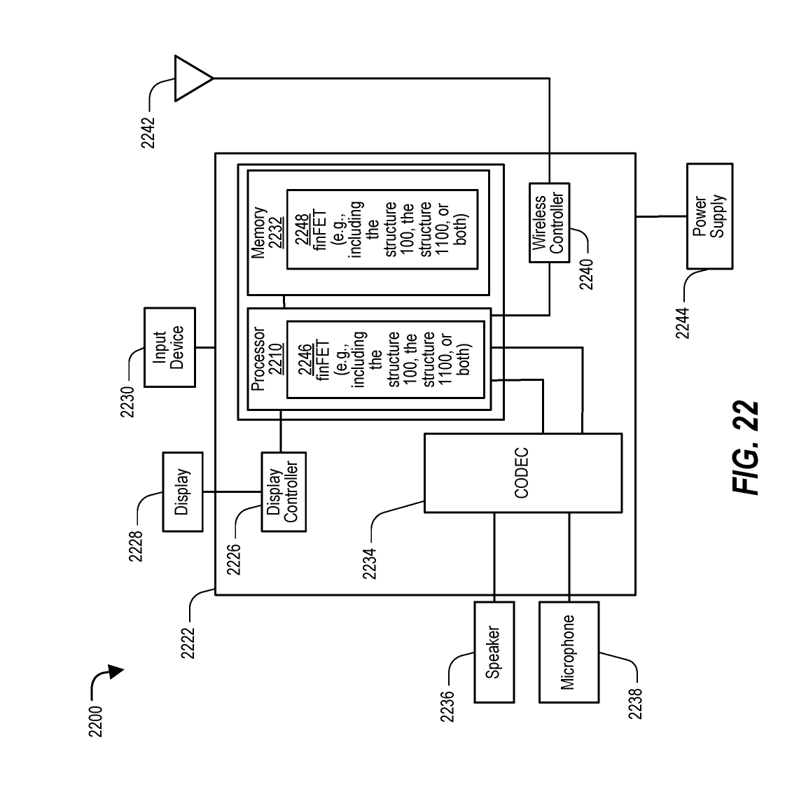

Referring to FIG. 22, a block diagram of a particular illustrative aspect of a wireless communication device 2200 is depicted. The wireless communication device 2200 includes a processor 2210, such as a digital signal processor (DSP), coupled to a memory 2232 (e.g., a random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art). The processor 2210 may include at least one finFET 2246 that incorporates the structure 100 of FIG. 1, the structure 1100 of FIG. 11, or both. The memory 2232 may include at least one finFET 2248 that incorporates the structure 100 of FIG. 1, the structure 1100 of FIG. 11, or both. For instance, at least one finFET that incorporates the structure 100, the structure 1100, or both may be incorporated into the processor 2210, the memory 2232, or both. In a particular aspect, the structure 100, the structure 1100, or both, may be formed according to the method 2100 of FIG. 21.

FIG. 22 also shows a display controller 2226 that is coupled to the processor 2210 and to a display 2228. A coder/decoder (CODEC) 2234 may also be coupled to the processor 2210. A speaker 2236 and a microphone 2238 may be coupled to the CODEC 2234.

FIG. 22 also indicates that a wireless controller 2240 may be coupled to the processor 2210 and may be further coupled to an antenna 2242. In a particular aspect, the processor 2210, the display controller 2226, the memory 2232, the CODEC 2234, and the wireless controller 2240 are included in a system-in-package or system-on-chip device 2222. In a particular aspect, an input device 2230 and a power supply 2244 are coupled to the system-on-chip device 2222. Moreover, in a particular aspect, as illustrated in FIG. 22, the display 2228, the input device 2230, the speaker 2236, the microphone 2238, the antenna 2242, and the power supply 2244 are external to the system-on-chip device 2222. However, each of the display 2228, the input device 2230, the speaker 2236, the microphone 2238, the antenna 2242, and the power supply 2244 may be coupled to a component of the system-on-chip device 2222, such as an interface or a controller.

In conjunction with the described implementations, an apparatus includes means for conducting charge carriers. For example, the means for conducting charge carriers may correspond to a fin 102 or a second fin 150 of FIGS. 1 and 11.

The apparatus may include a means for enhancing a mobility of charge carriers. For example, the means for enhancing the mobility of charge carriers may correspond to an epitaxial cladding layer. For instance, the means for enhancing the mobility of charge carriers may correspond to the first epitaxial layer 122, the second epitaxial layer 124, or the top epitaxial layer 123, as illustrated in FIG. 1. Alternatively, the means for enhancing the mobility of charge carriers may correspond to the first epitaxial layer 122 or the second epitaxial layer 124, as illustrated in FIG. 11. In an implementation, any of the first epitaxial layer 122, the second epitaxial layer 124, or the top epitaxial layer 123 may be planarized.

The means for conducting charge carriers may have a substantially three dimensional rectangular shape. For example, the fins 102, 150 in the cross-sectional views of FIGS. 1 and 11 may have a substantially three dimensional rectangular shape. In an implementation, the means for enhancing the mobility of charge carriers may include a first layer adjacent to a first interface of the means for conducting charge carriers. For example, the means for enhancing the mobility of charge carriers may correspond to the first epitaxial layer 122 of FIGS. 1 and 11, and the first interface of the means for conducting charge carriers may correspond to the first sidewall 110 of FIGS. 1 and 11. The means for enhancing the mobility of charge carriers may have a second layer adjacent to a second interface of the means for conducting charge carriers. For example, the means for enhancing the mobility of charge carriers may correspond to the second epitaxial layer 124 and the second interface of the means for conducting charge carriers may correspond to the second sidewall 112.

The apparatus may include a means for supporting the means for enhancing the mobility of charge carriers. For example, the means for supporting the means for enhancing the mobility or charge carriers may correspond to the first STI layer 104 depicted in FIGS. 1 and 11.

The means for conducting charge carriers and the means for enhancing the mobility of charge carriers may be integrated into various devices. For example, the means for conducting charge carriers and the means for enhancing the mobility of charge carriers may correspond to a device depicted in FIG. 1 or 11. The devices of FIG. 1 or 11 may be integrated into a mobile device, a set top box, a video player, an entertainment unit (e.g., a television), a navigation device, a vehicle (e.g., an automobile, boat, plane), a communication device, a personal digital assistant (PDA), a fixed location data unit, a satellite, an access point, a base station, a computer, or a combination thereof.

The means for enhancing the mobility of charge carriers may include an epitaxial material that has a substantially uniform thickness and that has a continuous lattice structure at an interface of the means for conducting charge carriers. For instance, the means for enhancing the mobility of charge carriers may be an epitaxial cladding layer that is formed from a III-V or II-VI semiconductor material. In particular, the means for enhancing the mobility of charge carriers may be a first epitaxial layer 122 that has been fabricated from a III-V semiconductor material and that has been planarized to a uniform thickness.

The apparatus may include a means for applying a voltage. For example, the means for applying the voltage may correspond to a gate electrode corresponding to the gate electrode 1004, 2004 of FIGS. 10 and 20. For example, a gate oxide layer 1002, 2002 can be formed on the structure 100 or the structure 1100 as depicted in FIGS. 10 and 20. A gate electrode 1004, 2004 can be deposited on the gate oxide layer 1002, 2002. For instance, conducting materials can be deposited onto the gate oxide layer 1002, 2002 to form the gate electrode 1004, 2004. A voltage can be applied to the gate electrode 1004, 2004.

Those of skill would further appreciate that the various illustrative logical blocks, configurations, modules, circuits, and algorithm steps described in connection with the aspects disclosed herein may be implemented as electronic hardware, computer software executed by a processor, or combinations of both. Various illustrative components, blocks, configurations, modules, circuits, and steps have been described above generally in terms of their functionality. Whether such functionality is implemented as hardware or processor executable instructions depends upon the particular application and design constraints imposed on the overall system. Skilled artisans may implement the described functionality in varying ways for each particular application, but such implementation decisions should not be interpreted as causing a departure from the scope of the present disclosure.

The steps of a method or algorithm described in connection with the aspects disclosed herein may be embodied directly in hardware, in a software module executed by a processor, or in a combination of the two. A software module may reside in random access memory (RAM), flash memory, read-only memory (ROM), programmable read-only memory (PROM), erasable programmable read-only memory (EPROM), electrically erasable programmable read-only memory (EEPROM), registers, hard disk, a removable disk, a compact disc read-only memory (CD-ROM), or any other form of non-transient storage medium known in the art. An exemplary storage medium is coupled to the processor such that the processor can read information from, and write information to, the storage medium. In the alternative, the storage medium may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal. A storage device is not a signal.

The previous description of the disclosed aspects is provided to enable a person skilled in the art to make or use the disclosed aspects. Various modifications to these aspects will be readily apparent to those skilled in the art, and the principles defined herein may be applied to other aspects without departing from the scope of the disclosure. Thus, the present disclosure is not intended to be limited to the aspects shown herein but is to be accorded the widest scope possible consistent with the principles and novel features as defined by the following claims.

1. A device comprising:
a substrate;
a shallow trench isolation (STI) layer formed on the substrate;
a fin extending from the substrate through the STI layer; and
an epitaxial cladding layer on a sidewall of the fin, the epitaxial cladding layer having a substantially uniform thickness and having a continuous lattice structure at an interface with the sidewall.

2. The device of claim 1, wherein the substrate comprises a (100) substrate, wherein crystals of a material comprising at least a first sidewall of the fin are oriented in a <110> crystallographic direction, and wherein crystals of the material comprising a long axis of the fin are oriented in the <110> crystallographic direction.

3. The device of claim 1, wherein the substantially uniform thickness is less than a critical thickness associated with formation of a layer of a superlattice structure.

4. The device of claim 1, wherein the substantially uniform thickness is in a range of 3 nanometers to 10 nanometers.

5. The device of claim 1, further comprising:
a second epitaxial cladding layer on a second sidewall of the fin,
wherein the epitaxial cladding layer is a first layer of a superlattice structure, the fin is a second layer of the superlattice structure, and the second epitaxial cladding layer is a third layer of the superlattice structure.

6. The device of claim 1, wherein the epitaxial cladding layer includes a first material that has a greater carrier mobility than a second material of the fin, and wherein the STI layer is positioned between the substrate and the epitaxial cladding layer.

7. The device of claim 1, wherein the fin includes silicon (Si), and wherein the STI layer comprises silicon oxide (SiO), silicon oxynitride (SiON), or both.

8. The device of claim 1, wherein the epitaxial cladding layer includes indium-antimony (InSb), germanium (Ge), indium-gallium-arsenide (InGaAs), or silicon germanium (SiGe).

9. A device comprising:
a substrate;
a shallow trench isolation (STI) layer formed on the substrate;
a fin extending from the substrate through the STI layer; and
a planarized conformal epitaxial layer covering an active area of the fin, the planarized conformal epitaxial layer including a first epitaxial layer on a sidewall of the fin, wherein the first epitaxial layer has a substantially uniform thickness and has a continuous lattice structure at an interface with the fin.

10. The device of claim 9, wherein the planarized conformal epitaxial layer includes a top epitaxial layer on a surface of the fin that is substantially perpendicular to the sidewall, and wherein the top epitaxial layer has a first thickness that is distinct from the substantially uniform thickness of the first epitaxial layer.

11. The device of claim 10, further comprising:
a second fin; and
a second top epitaxial layer on a second surface of the second fin, the second surface substantially perpendicular to a second sidewall of the second fin,
wherein a first height of the active area of the fin is distinct from a second height of a second active area of the second fin,
wherein the first thickness is distinct from a second thickness of the second top epitaxial layer, and
wherein a first sum of the first height and the first thickness is substantially the same as a second sum of the second height and the second thickness.

12. A semiconductor device comprising:
a substrate;
a shallow trench isolation (STI) layer formed on the substrate;
a fin extending from the substrate through the STI layer; and
a planarized epitaxial cladding layer on a sidewall of the fin, the planarized epitaxial cladding layer having a substantially uniform thickness and having a continuous lattice structure at an interface with the sidewall.

13. The semiconductor device of claim 12, wherein the substantially uniform thickness is greater than or equal to 3 nanometers and less than or equal to 10 nanometers.

14. The semiconductor device of claim 12, wherein a first material of the fin has a first band gap, wherein a second material of the epitaxial cladding layer has a second band gap, and wherein the first band gap is distinct from the second band gap.

15. The semiconductor device of claim 12, wherein the substrate comprises a silicon-on-insulator substrate.

16. The semiconductor device of claim 12, wherein the epitaxial cladding layer is comprised of a II-VI semiconductor material or III-V semiconductor material.

17. The semiconductor device of claim 12, further comprising a gate or a capping layer formed over a surface of the fin, wherein the gate or capping layer is substantially perpendicular to the sidewall of the fin.

18. The semiconductor device of claim 12, further comprising:
a second fin;
a second planarized epitaxial cladding layer on a second sidewall of the fin, the second planarized epitaxial cladding layer having a substantially uniform thickness and having a continuous lattice structure at a second interface with the second sidewall; and
a gate intersecting the fin and the second fin.

19. The semiconductor device of claim 18, wherein the planarized epitaxial cladding layer, the second planarized epitaxial cladding layer, the sidewall, and the second sidewall are substantially perpendicular to the substrate.

20. The semiconductor device of claim 18, wherein the substrate comprises a (100) substrate, and wherein the second interface is positioned substantially in a <110> crystallographic direction of the (100) substrate.

21. The semiconductor device of claim 12 incorporated into a processor or a memory of an electronic device.

22. The semiconductor device of claim 12, wherein the STI layer is above the substrate and below the planarized epitaxial cladding layer.

23. The semiconductor device of claim 12, wherein the STI layer comprises a dielectric material.

24. An apparatus comprising:
means for isolating formed on a substrate; and
means for conducting charge carriers extending from the substrate through the means for isolating; and
means for enhancing a mobility of the charge carriers, the means for enhancing the mobility of the charge carriers positioned to conform to a shape of the means for conducting, wherein the means for enhancing the mobility of the charge carriers comprises an epitaxial material that has a substantially uniform thickness and that has a continuous lattice structure at an interface of the means for conducting.

25. The apparatus of claim 24, wherein the means for conducting and the means for enhancing are integrated into at least one of a set top box, a video player, an entertainment unit, a navigation device, a communication device, a personal digital assistant (PDA), a fixed location data unit, or a computer.

26. The apparatus of claim 24, wherein a surface of the means for enhancing the mobility of charge carriers is planarized.

27. The apparatus of claim 24, further comprising a means for applying a voltage, the means for applying the voltage positioned above the means for conducting and the means for enhancing the mobility of charge carriers.

28. The apparatus of claim 24, wherein the means for conducting has a substantially three dimensional rectangular shape, and wherein the means for enhancing the mobility of the charge carriers has a first layer adjacent to a first interface of the means for conducting and a second layer adjacent to a second interface of the means for conducting.

29. The apparatus of claim 28, wherein the first layer, the second layer, or both are planarized.

30. The apparatus of claim 24, further comprising a means for supporting the means for enhancing the mobility of charge carriers.
